(19) United States
(12) Patent Application Publication
(10) Pub. No.: US 2025/0008771 A1
(43) Pub. Date: Jan. 2, 2025

(54) DISPLAY DEVICE AND DISPLAY PANEL

(71) Applicant: LG Display Co., Ltd., Seoul (KR)

(72) Inventors: Hyunguk Jang, Paju-si (KR); EuiHyun Chung, Paju-si (KR); JoungMi Choi, Paju-si (KR)

(73) Assignee: LG Display Co., Ltd., Seoul (KR)

(21) Appl. No.: 18/751,974

(22) Filed: Jun. 24, 2024

(30) Foreign Application Priority Data
Jun. 27, 2023 (KR) 10-2023-0082777

(51) Int. Cl. H10K 59/121; H10K 59/126; H10K 59/131

(52) U.S. Cl. CPC H10K 59/121; H10K 59/126; H10K 59/131

(57) ABSTRACT

A display device according to one or more examples may include a substrate, a display area with a first display area and a second display area, a non-display area, a base circuit layer located on the substrate and including a gate-in-panel circuit and a subpixel circuit array disposed in the display area, and a light emitting device layer located on the base circuit layer and including two or more first light emitting devices disposed in the first display area and two or more second light emitting devices disposed in the second display area. The subpixel circuit array may include one first subpixel circuit configured to simultaneously drive the two or more first light emitting devices, and disposed in the second display area, and two or more second subpixel circuits configured to respectively drive the two or more second light emitting devices, and disposed in the second display area.

### CROSS REFERENCE TO RELATED APPLICATION

This application claims the benefit of and priority to Korean Patent Application No. 10-2023-0082777, filed on Jun. 27, 2023, the entirety of which is incorporated herein by reference for all purposes as if fully set forth herein.

### BACKGROUND

### 1. Technical Field

Embodiments of the present disclosure relate to display apparatuses, and particularly to, for example, without limitation, a display device and a display panel.

### 2. Description of the Related Art

A display device may include a display panel on which a plurality of data lines and a plurality of gate lines are arranged, a data driving circuit for driving the plurality of data lines, and a gate driving circuit for driving the plurality of gate lines. Here, the display panel may include a display area where an image is displayed and a non-display area where the image is not displayed.

In the case of a general display device, a gate driving circuit may be connected to or disposed in a non-display area (also referred to as a bezel) of the display panel. Accordingly, the non-display area (i.e., bezel) of the display panel is required to have a specific size sufficient to connect or place the gate driving circuit.

The description of the related art should not be assumed to be prior art merely because it is mentioned in or associated with this section. The description of the related art may include information that describes one or more aspects of the subject technology, and the description in this section does not limit the invention.

### SUMMARY

The inventors of the present disclosure have recognized the problems and disadvantages of the related art and have performed extensive research and experiments. The inventors of the present disclosure have thus invented a new display device and a new display panel that substantially obviate one or more problems due to limitations and disadvantages of the related art.

One or more example embodiments of the present disclosure may provide a display panel and a display device having an extremely narrow bezel structure.

One or more example embodiments of the present disclosure may provide a display panel and a display device in which a gate-in-panel circuit, which is a gate driving circuit of the gate-in-panel type, is disposed in the display area.

One or more example embodiments of the present disclosure may provide a display panel and a display device in which a gate-in-panel circuit is disposed to overlap a light emitting device layer in the vertical direction.

One or more example embodiments of the present disclosure may provide a display panel and a display device having a structure capable of shielding the electric field between a gate-in-panel circuit and a light emitting device layer.

One or more example embodiments of the present disclosure may provide a display panel and a display device in which a connection structure of a cathode and a base voltage line is disposed within the display area.

A display device according to one or more example embodiments of the present disclosure may include a substrate, a display area with a first display area and a second display area, a non-display area outside the display area, a base circuit layer located on the substrate and including a gate-in-panel circuit and a subpixel circuit array disposed in the display area, and a light emitting device layer located on the base circuit layer and including two or more first light emitting devices disposed in the first display area and two or more second light emitting devices disposed in the second display area.

The subpixel circuit array may include one first subpixel circuit configured to simultaneously drive the two or more first light emitting devices, and disposed in the second display area, and two or more second subpixel circuits configured to respectively drive the two or more second light emitting devices, and disposed in the second display area.

The gate-in-panel circuit may be disposed in the first display area, and the subpixel circuit array may be disposed in the second display area.

At least some of the two or more first light emitting devices may overlap with at least a portion of the gate-in-panel circuit, and at least some of the two or more second light emitting devices may overlap with at least a portion of the subpixel circuit array.

The display device according to one or more example embodiments of the present disclosure may further include an extension link (which may also be referred to as an anode extension link if a pixel electrode is an anode) connecting the one first subpixel circuit disposed in the second display area to the two or more first light emitting devices disposed in the first display area.

The extension link may include a metal located between the base circuit layer and the light emitting device layer.

The first display area may be located between the non-display area and the second display area.

The display device according to one or more example embodiments of the present disclosure may further include a shielding layer located between the gate-in-panel circuit and the light emitting device layer.

In the case that the display device according to one or more example embodiments of the present disclosure further includes an extension link connecting the one first subpixel circuit to two or more pixel electrodes included in the two or more first light emitting devices, the shielding layer may be located between the extension link and the gate-in-panel circuit, and at least a portion of the shielding layer may overlap with the extension link and the gate-in-panel circuit. The shielding layer may be disposed in the first display area.

The display device according to one or more example embodiments of the present disclosure may further include a base voltage line to which the base voltage is applied, and a cathode connection pattern for electrically connecting the cathode and the base voltage line.

The display device according to one or more example embodiments of the present disclosure may further include an anode extension link connecting the one first subpixel circuit to the two or more first light emitting devices.

The cathode connection pattern may include a first cathode connection pattern disposed on the same metal layer as the anode extension link.

The base voltage line and the cathode connection pattern may be located in the non-display area.

The base voltage line may be disposed outside the gate-in-panel circuit.

The display device according to one or more example embodiments of the present disclosure may further include a shielding layer disposed in the first display area and located between the gate-in-panel circuit included in the base circuit layer and the light emitting device layer. In this case, the shielding layer may be electrically connected to the cathode connection pattern.

The base voltage line and the cathode connection pattern may be located in the display area.

The cathode may be electrically connected to at least one of the base voltage line and the cathode connection pattern located below a bank through a hole in the bank located between the two or more second anodes.

A display panel according to one or more example embodiments of the present disclosure may include a substrate, a display area with a first display area and a second display area, a non-display area outside the display area, two or more first light emitting devices disposed in the first display area, a plurality of second light emitting devices disposed in the second display area, one first subpixel circuit commonly connected to the two or more first light emitting devices, and two or more second subpixel circuits. Each of the two or more second subpixel circuits may be connected to one second light emitting device among the plurality of second light emitting devices.

The display panel according to one or more example embodiments of the present disclosure may further include a gate-in-panel circuit disposed in the first display area.

The display panel according to one or more example embodiments of the present disclosure may further include an extension link commonly connecting a pixel electrode of each of the two or more first light emitting devices to the one first subpixel circuit.

The display panel according to one or more example embodiments of the present disclosure may further include a shielding layer disposed between the gate-in-panel circuit and the extension link.

A display apparatus according to one or more example embodiments of the present disclosure may include a substrate, a display area, a light emitting device layer disposed over the substrate and including a plurality of light emitting devices disposed in the display area, and a base circuit layer disposed between the light emitting device layer and the substrate and including a gate driving circuit and subpixel circuits.

The gate driving circuit and the subpixel circuits may be disposed in the display area, at least a portion of the gate driving circuit may overlap with one or more first light emitting devices among the plurality of light emitting devices, and at least a portion of the subpixel circuits may overlap with one or more second light emitting devices among the plurality of light emitting devices.

A cathode may be disposed on emission layers of the plurality of light emitting devices. The cathode may overlap with the at least a portion of the gate driving circuit and the at least a portion of the subpixel circuits.

The gate driving circuit may transmit a scan signal or an emission control signal to a scan line or an emission control line of the subpixel circuits. One or more of the subpixel circuits may drive the one or more second light emitting devices.

According to the one or more example embodiments of the present disclosure, there may provide a display panel and a display device having an extremely narrow bezel structure.

According to the one or more example embodiments of the present disclosure, a gate-in-panel circuit which is a gate driving circuit of the gate-in-panel type may be disposed in the display area, thereby reducing the size of the non-display area.

According to one or more example embodiments of the present disclosure, the gate-in-panel circuit is arranged to overlap the light emitting device layer in the vertical direction, thereby reducing the size of the non-display area.

According to one or more example embodiments of the present disclosure, there may provide a structure capable of shielding the electric field between the gate-in-panel circuit and the light emitting device layer, thereby eliminating unnecessary electrical effect between the gate-in-panel circuit and the light emitting device layer.

According to one or more example embodiments of the present disclosure, a connection structure between the cathode and the base voltage line is disposed in the display area, thereby further reducing the size of the non-display area.

According to one or more example embodiments of the present disclosure, the gate driving circuit and the cathode connection structure are disposed in the display area, so that a length of a path through which a gate signal output from the gate driving circuit is supplied to the subpixel circuits may be shortened, and a length of the cathode connection structure may also be shortened. The hangers on the structure may also be shortened. Accordingly, it is possible to reduce the metal used in the path, thereby enabling the lightening of display panel and a display device.

Other apparatuses, devices, panels, methods, features and advantages will be, or will become, apparent to one with skill in the art upon examination of the drawings and detailed description herein. It is intended that all such apparatuses, devices, panels, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a system configuration diagram of a display device according to one or more example embodiments of the present disclosure.

FIG. 2 illustrates a display panel according to one or more example embodiments of the present disclosure.

FIGS. 3 and 4 illustrate a vertical structure and planar structure of a display area of a display panel according to one or more example embodiments of the present disclosure.

FIGS. 5 and 6 are examples of plan views of partial areas of the display panel of FIG. 4.

FIG. 7 illustrates the correspondence relationship between subpixel circuits and light emitting devices in a display panel according to one or more example embodiments of the present disclosure.

FIG. 8 illustrates only the correspondence relationship between first subpixel circuits and first light emitting devices in a display panel according to one or more example embodiments of the present disclosure.

FIG. 9 is an equivalent circuit of a subpixel disposed on or in a display panel according to one or more example embodiments of the present disclosure.

FIGS. 10A and 10B illustrate a gate-in-panel circuit disposed on or in a display panel according to one or more example embodiments of the present disclosure.

FIG. 11 is an equivalent circuit of a subpixel disposed on or in a display panel according to one or more example embodiments of the present disclosure.

FIG. 12 illustrates a gate-in-panel circuit disposed on or in a display panel according to one or more example embodiments of the present disclosure.

FIG. 13 illustrates a gate-in-panel circuit disposed on or in a display panel according to one or more example embodiments of the present disclosure.

FIG. 14 illustrates a vertical structure of a display panel according to one or more example embodiments of the present disclosure.

FIG. 15 is a cross-sectional view illustrating a vertical structure of a display panel according to one or more example embodiments of the present disclosure.

FIG. 16 is another plan view of a partial area of a display panel according to one or more example embodiments of the present disclosure.

FIG. 17 is another cross-sectional view illustrating a vertical structure of a display panel according to one or more example embodiments of the present disclosure.

FIG. 18 is another cross-sectional view illustrating a vertical structure of a display panel according to one or more example embodiments of the present disclosure.

FIG. 19 is another cross-sectional view illustrating a vertical structure of a display panel according to one or more example embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate (ly),” or “direct (ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” may apply, for example, to a separate circuit or structure, an integrated circuit, a computational block of a circuit device, or any structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

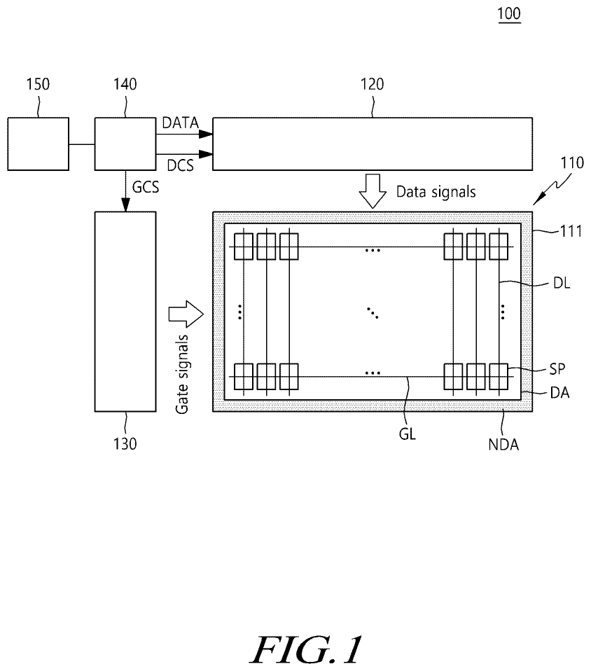

FIG. 1 is a system configuration diagram of a display device 100 according to one or more example embodiments of the present disclosure.

Referring to FIG. 1, a display device 100 according to one or more example embodiments of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

In a display panel 110 according to one or more example embodiments of the present disclosure, the non-display area NDA may be very small.

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three which do not include the pad area may be very small in size.

For another example, a boundary area between the display area DA and the non-display area NDA may be bent so that the non-display area NDA may be located below the display area. In this case, when the user looks at the display device 100 from the front, there may be little or no non-display area NDA visible to the user.

Various types of signal lines for driving a plurality of subpixels SP may be disposed on the substrate 111 of the display panel 110.

The display device 100 according to one or more example embodiments of the present disclosure may be a liquid crystal display device or the like, or may be a self-luminous display device in which the display panel 110 emits light by itself. When the display device 100 according to one or more example embodiments of the present disclosure is a self-luminous display device, each of the plurality of subpixels SP may include a light emitting device.

For example, the display device 100 according to one or more example embodiments of the present disclosure may be an organic light emitting display device in which a light emitting device is implemented as an organic light emitting diode (OLED). For another example, the display device 100 according to one or more example embodiments of the present disclosure may be an inorganic light emitting display device in which the light emitting device is implemented as an inorganic-based light emitting diode. For another example, the display device 100 according to one or more example embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuit 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, and so on, the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to one or more example embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display device 100 according to one or more example embodiments of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA).

In the present disclosure, a gate driving circuit 130 built into the display panel 110 as a gate-in-panel type may be referred to as a “gate-in-panel circuit.”

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 230 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, or another component, and may be electrically connected to the data driving circuit 120 and the gate driving circuit 130 through a printed circuit board, a flexible printed circuit.

The display controller 140 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI).

In order to provide not only an image display function but also a touch sensing function, the display device 100 according to one or more example embodiments of the present disclosure may include a touch sensor and a touch sensing circuit for detecting an occurrence of a touch by a touch object such as a finger or pen or detecting a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate SUB along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, or another object). According to the self-capacitance sensing method, each of the plurality of touch electrodes may serve as a driving touch electrode and a sensing touch electrode. The touch driving circuit 260 may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit 260 and the data driving circuit 120 may be implemented as separate devices or as one device.

The display device 100 may further include a power supply circuit which supplies various types of power to the display driving circuit and/or the touch sensing circuit.

The display device 100 according to one or more example embodiments of the present disclosure may be a mobile terminal such as a smart phone or tablet, or a monitor or television of various sizes, but is not limited thereto, and may be a display of various types and sizes capable of displaying information or images.

The display device 100 according to one or more example embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

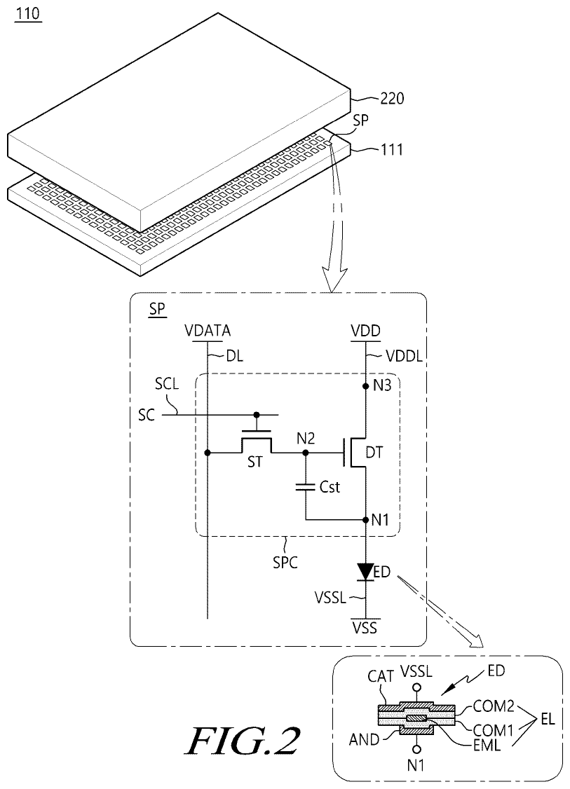

FIG. 2 illustrates a display panel 110 according to one or more example embodiments of the present disclosure.

Referring to FIG. 2, the display panel 110 may include a substrate 111 disposed in a plurality of subpixels SP and an encapsulation layer 220 on the substrate 111. Here, the encapsulation layer 220 may also be referred to as an encapsulation substrate or an encapsulation portion.

Referring to FIG. 2, when the display device 100 according to one or more example embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC. The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common pixel driving voltage including a first driving voltage VDD and a second driving voltage VSS may be applied to the subpixel SP in order to drive the subpixel SP.

The light emitting device ED may include an anode AND, a device intermediate layer EL, and a cathode CAT. The device intermediate layer EL may be a layer disposed between the anode AND and the cathode CAT, and may include an emission layer EML.

In the case that the light emitting device ED is an organic light emitting device, the device intermediate layer EL may include the emission layer EML, a first common layer COM1 between the anode AND and the emission layer EML, and a second common layer COM2 between the emission layer EML and the cathode. The emission layer EML may be disposed in each subpixel SP. In comparison, the first common layer COM1 and the second common layer COM2 may be commonly disposed across a plurality of subpixels SP. The emission layer EML may be disposed in each emission area, and the first common layer COM1 and the second common layer COM2 may be commonly disposed across a plurality of emission areas and non-emission areas.

For example, the first common layer COM1 may include a hole injection layer HIL and a hole transport layer HTL, and the second common layer COM2 may include an electron transport layer ETL and an electron injection layer EIL. The hole injection layer may inject holes from the anode AND to the hole transport layer, the hole transport layer may transport holes to the emission layer EML, the electron injection layer may inject electrons from the cathode CAT to the electron transport layer, and the electron transport layer may transport electrons to the emission layer EML.

For example, the cathode CAT may be electrically connected to a second driving voltage line VSSL. A second driving voltage VSS, which is a type of common pixel driving voltage, may be applied to the cathode CAT through the second driving voltage line VSSL. The anode AND may be electrically connected to a first node N1 of the driving transistor DT of each subpixel SP. In the present disclosure, the second driving voltage VSS may also be referred to as a base voltage VSS, and the second driving voltage line VSSL may also be referred to as a base voltage line VSSL.

For example, the anode AND may be a pixel electrode disposed in each subpixel SP, and the cathode CAT may be a common electrode commonly disposed in a plurality of subpixels SP. For another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of an anode AND, a device intermediate layer EL and a cathode CAT. A predetermined emission area may be formed by each light emitting device ED. For example, the emission area of each light emitting device ED may include an area where the anode AND, the device intermediate layer EL and the cathode CAT overlap.

For example, the light emitting device ED may be an organic light emitting diode (OLED), an inorganic light emitting diode, or a quantum dot light emitting device. For example, in the case that the light emitting device ED is an organic light emitting diode OLED, the device intermediate layer EL in the light emitting device ED may include an organic device intermediate layer EL containing an organic material.

The driving transistor DT may be a driving transistor for supplying driving current to the light emitting device ED. The driving transistor DT may be connected between a first driving voltage line VDDL and the light emitting device ED.

The driving transistor DT may include a first node N1 electrically connected to the light emitting device ED, a second node N2 to which the data signal VDATA is applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled to be turned on or off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

At least a portion of the subpixel circuit SPC may overlap with at least a portion of the light emitting device ED in a vertical direction. Alternatively, the subpixel circuit SPC may not overlap with the light emitting device ED in the vertical direction.

As shown in FIG. 2, the subpixel circuit SPC may have 2T-1C structure including two transistors T1 and T2 and one capacitor Cst. In some case, Depending on this, the subpixel circuit SPC may further include one or more transistors or one or more capacitors.

For example, the subpixel circuit SPC may have an 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 220 may be disposed on the display panel 110 to prevent oxygen from penetrating into the circuit elements (particularly, the light emitting device ED). The encapsulation layer 220 may be configured in various shapes to prevent the light emitting device ED from coming into contact with moisture or oxygen.

The display panel 110 according to one or more example embodiments of the present disclosure may have a top emission structure or a bottom emission structure.

The display device 100 according to one or more example embodiments of the present disclosure may have an extremely narrow bezel structure in which the non-display area NDA of the display panel 110 is very small or almost absent. Hereinafter, an extremely narrow bezel structure of the display panel 110 of the display device 100 is described according to one or more example embodiments of the present disclosure.

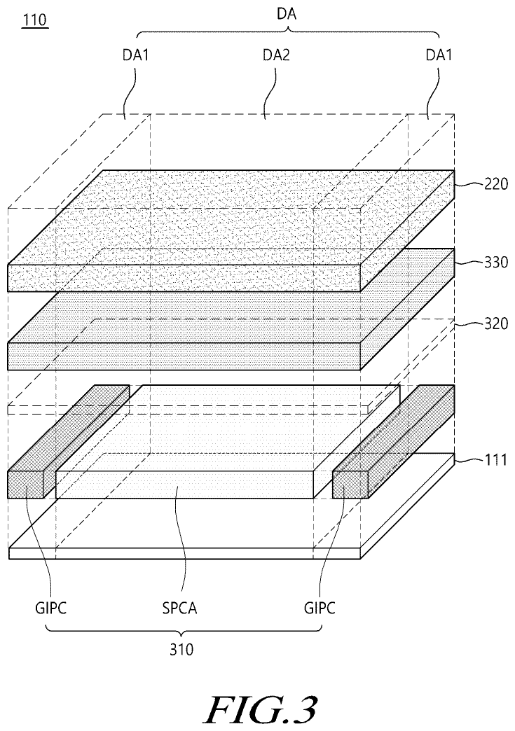

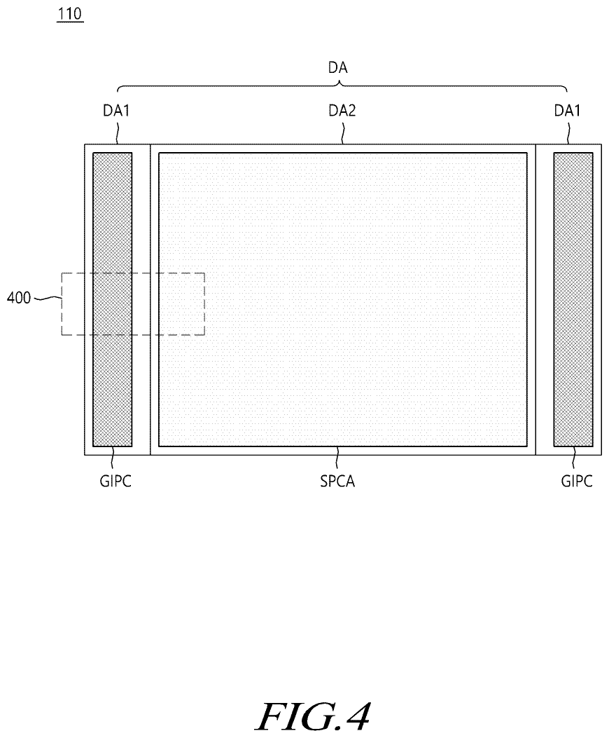

FIGS. 3 and 4 illustrate a vertical structure and planar structure of a display area DA of a display panel 110 according to one or more example embodiments of the present disclosure.

Referring to FIG. 3, the display panel 110 according to one or more example embodiments of the present disclosure may include a substrate 111, a base circuit layer 310, a light emitting device layer 330, and an encapsulation layer 220.

Referring to FIGS. 3 and 4, the display area DA may include a first display area DA1 and a second display area DA2.

As shown in FIGS. 3 and 4, the first display area DA1 may be disposed on both one side and the other side of the second display area DA2. Alternatively, the first display area DA1 may be disposed only on one side or the other side of the second display area DA2.

Referring to FIGS. 3 and 4, a base circuit layer 310 may be located on the substrate 111, and may include a gate-in-panel circuit GIPC and a subpixel circuit array SPCA disposed in the display area DA.

Referring to FIGS. 3 and 4, a light emitting device layer 330 may be located on the base circuit layer 310. A plurality of light emitting devices ED may be disposed in the light emitting device layer 330. The plurality of light emitting devices ED disposed in the light emitting device layer 330 may include a plurality of light emitting devices ED disposed in the first display area DA1 and a plurality of light emitting devices ED disposed in the second display area DA2.

Referring to FIGS. 3 and 4, the subpixel circuit array SPCA may include a plurality of subpixel circuits SPC. Referring to FIGS. 3, 4 and 7, the plurality of subpixel circuits SPC may include one first subpixel circuit SPC1 configured to simultaneously drive two or more light emitting devices ED disposed in the first display area DA1, and two or more second subpixel circuits SPC2 configured to respectively drive two or more light emitting devices ED disposed in the second display area DA2.

Referring to FIGS. 3 and 4, one first subpixel circuit SPC1 may be placed in the second display area DA2 among the first display area DA and the second display area DA2 included in the display area DA.

Two or more second subpixel circuits SPC2 may be disposed in the second display area DA2 among the first display area DA1 and the second display area DA2 included in the display area DA.

Referring to FIGS. 3 and 4, the gate-in-panel circuit GIPC may be disposed in the first display area DA1. The subpixel circuit array SPCA may be disposed in the second display area DA2.

At least some of the two or more light emitting devices ED disposed in the first display area DA1 may overlap with at least a portion of the gate-in-panel circuit GIPC.

At least some of the two or more second light emitting devices ED2 disposed in the second display area DA2 may overlap with at least a portion of the subpixel circuit array SPCA.

One first subpixel circuit SPC1 may include a first driving transistor DT for supplying a driving current to two or more light emitting devices ED disposed in the first display area DA1, and a first scan transistor ST connected between one of the gate node, source node and drain node of the first driving transistor DT and a first data line DL.

Each of the two or more second subpixel circuits SPC2 may include a second driving transistor DT for supplying a driving current to a corresponding light emitting device ED among the two or more light emitting devices ED disposed in the second display area DA2, and a second scan transistor ST connected between one of the gate node, source node and drain node of the second driving transistor DT and a second data line DL.

Referring to FIG. 3, the display panel 110 according to one or more example embodiments of the present disclosure may further include an anode extension link layer 320 between the base circuit layer 310 and the light emitting device layer 330.

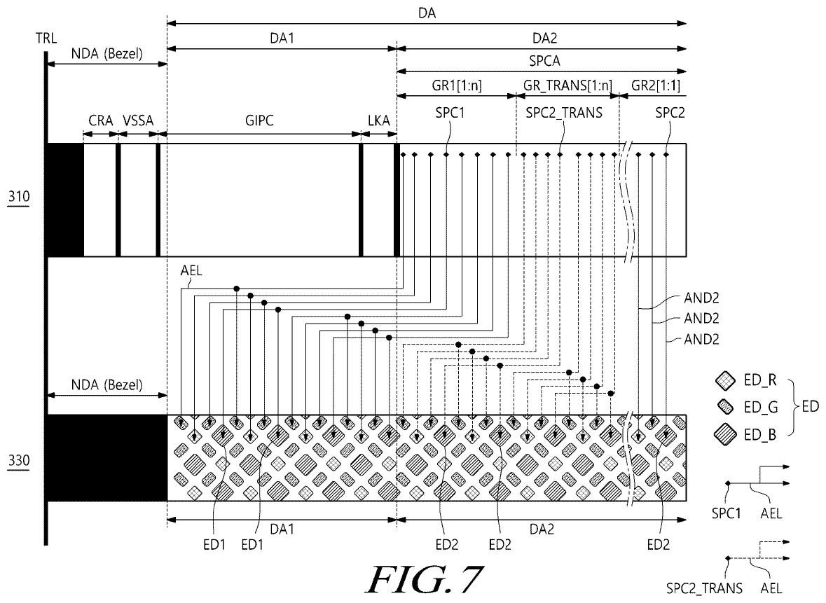

At least one anode extension link (which may also be referred to as an extension link or a connection pattern shown as AEL in FIG. 7) may be disposed in the anode extension link layer 320. At least one anode extension link may electrically connect at least one first subpixel circuit SPC1 disposed in the second display area DA2 and a plurality of light emitting devices ED disposed in the first display area DA1.

As described above, in the display panel 110 according to one or more example embodiments of the present disclosure, the gate-in-panel circuit GIPC may be disposed in the first display area DA1 included in the display area DA, thereby reducing a bezel corresponding to the non-display area NDA.

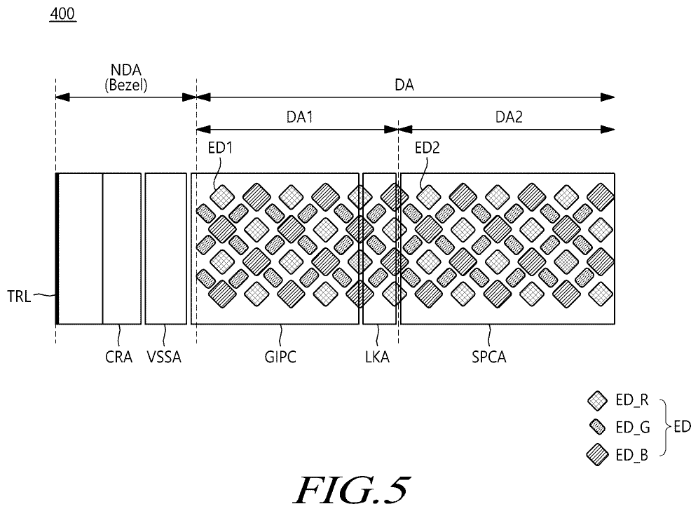

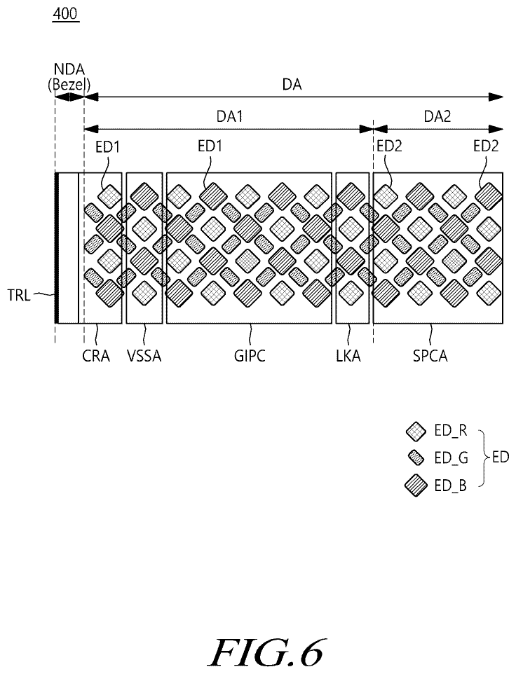

FIGS. 5 and 6 are plan views of a partial area 400 of the display panel 110 of FIG. 4.

Referring to FIGS. 5 and 6, the display panel 110 may include a display area DA and a non-display area NDA1, and the display area DA may include a first display area DA1 and the second display area DA2. The non-display area NDA may also be referred to as a bezel.

Referring to FIGS. 5 and 6, the first display area DA1 may be located between the non-display area NDA and the second display area DA2.

Referring to FIGS. 5 and 6, the display area DA may include a plurality of light emitting devices ED. For example, the plurality of light emitting devices ED may include a red light emitting device ED_R for emitting red light, a green light emitting device ED_G for emitting green light, and a blue light emitting device ED_G for emitting blue light ED_B.

Referring to FIGS. 5 and 6, the plurality of light emitting devices ED disposed in the display area DA may include a plurality of first light emitting devices ED1 disposed in the first display area DA1 and a plurality of light emitting devices ED2 disposed in the display area DA2.

Referring to FIGS. 5 and 6, a subpixel circuit array SPCA may be disposed in the second display area DA2. The subpixel circuit array SPCA may include a plurality of subpixel circuits SPC.

The plurality of subpixel circuits SPC may include at least one first subpixel circuit SPC for driving a plurality of first light emitting devices ED1 disposed in the first display area DA1, a plurality of second subpixel circuits SPC for driving a plurality of second light emitting devices ED2 disposed in the second display area DA2.

Referring to FIGS. 5 and 6, all or part of the gate-in-panel circuit GIPC may be disposed in the first display area DA1.

Referring to FIGS. 5 and 6, the display panel 110 according to one or more example embodiments of the present disclosure may include a link area LKA where a plurality of links are disposed to transmit various gate signals output from the gate-in-panel circuit GIPC to the subpixel circuit array SPCA.

For example, the links disposed in the link area LKA may electrically connect output points of the gate-in-panel circuit GIPC and the gate lines GL. In the case that the output points of the gate-in-panel circuit GIPC is a first metal layer and the gate lines GL are a second metal layer different from the first metal layer, the links may include a jumping metal which connects the first metal layer and the second metal layer to each other.

Referring to FIGS. 5 and 6, the link area LKA may be located between the gate-in-panel circuit GIPC and the subpixel circuit array SPCA.

The link area LKA may be included in the first display area DA1.

Referring to FIGS. 5 and 6, the display panel 110 according to one or more example embodiments of the present disclosure may further include a base voltage line area VSSA in which the base voltage line VSSL is disposed.

Referring to FIGS. 5 and 6, the base voltage line area VSSA may be placed further outside the gate-in-panel circuit GIPC. That is, the base voltage line area VSSA may be located closer to a trimming line TRL than the gate-in-panel circuit GIPC. Here, the trimming line TRL may be an end cutting point of the substrate 111 of the display panel 110.

For example, as shown in FIG. 5, the base voltage line area VSSA may be located further outside the gate-in-panel circuit GIPC, and may be included in the non-display area NDA. In this case, the base voltage line VSSL may not overlap the first light emitting device ED1 disposed in the first display area DA1.

For another example, as shown in FIG. 6, the base voltage line area VSSA may be located further outside the gate-in-panel circuit GIPC, but may be included in the first display area DA1. In this case, the base voltage line VSSL may overlap the first light emitting device ED1 disposed in the first display area DA1.

Referring to FIGS. 5 and 6, the display panel 110 according to one or more example embodiments of the present disclosure may include a crack management area CRA in which a crack detection line and/or a crack stopper pattern is disposed.

For example, as shown in FIG. 5, the crack management area CRA may be included in the non-display area NDA. In this case, the crack detection line and/or the crack stopper pattern may not overlap with the first light emitting device EDI disposed in the first display area DA1.

For another example, as shown in FIG. 6, the crack management area CRA may be included in the first display area DA1. In this case, the crack detection line and/or the crack stopper pattern may overlap the first light emitting device ED1 disposed in the first display area DA1.

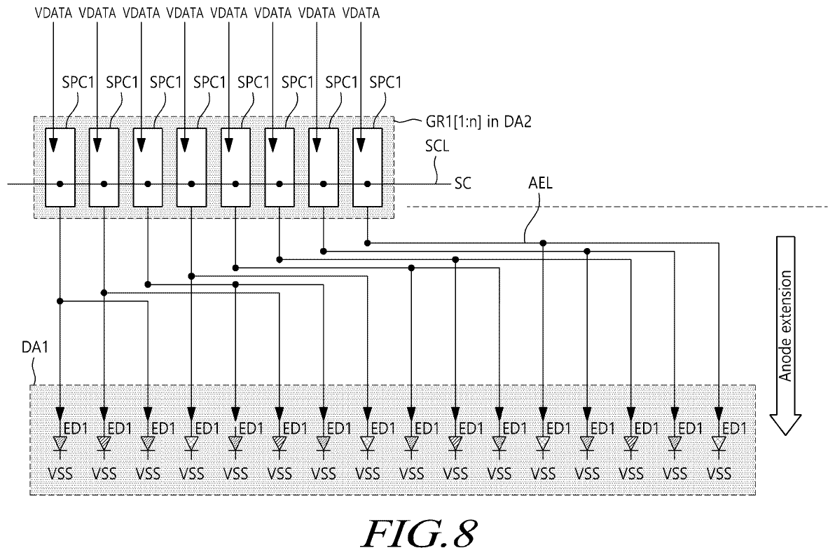

FIG. 7 illustrates the correspondence relationship between the subpixel circuits SPC1, SPC2_TRANS and SPC2 and the light emitting devices ED1 and ED2 in the display panel 110 according to one or more example embodiments of the present disclosure. FIG. 8 illustrates only the correspondence relationship between the first subpixel circuits SPC1 and the first light emitting device ED1 in the display panel 110 according to one or more example embodiments of the present disclosure. However, FIG. 7 is illustrated according to the planar arrangement structure of FIG. 5.

Referring to FIG. 7, based on a planar structure, the display panel 110 may include a display area DA and a non-display area NDA. The display area DA may include a first display area DA1 and a second display area DA2.

Referring to FIG. 7, based on a vertical structure, the display panel 110 may include a base circuit layer 310 and a light emitting device layer 330.

Referring to FIG. 7, in the base circuit layer 310, all or most of the gate-in-panel circuit GIPC may be disposed in the first display area DA1. In the base circuit layer 310, a subpixel circuit array SPCA including subpixel circuits SPC1, SPC2_TRANS and SPC2 may be disposed in the second display area DA2.

Referring to FIG. 7, in the base circuit layer 310, the link area LKA may be disposed in the first display area DA1 or the second display area DA2, or may be disposed across the first display area DA1 and the second display area DA2.

Referring to FIG. 7, a plurality of light emitting devices ED disposed on or in the light emitting device layer 330 may be disposed in the display area DA. The plurality of light emitting devices ED disposed in the light emitting device layer 330 may include a plurality of first light emitting devices ED1 disposed in the first display area DA1 and a plurality of second light emitting devices ED2 disposed in the second display area DA2.

Referring to FIG. 7, a plurality of subpixel circuits SPC included in the subpixel circuit array SPCA may include at least one first subpixel circuit SPC1 configured to drive a plurality of first light emitting devices EDI disposed in the first display area DA1, and a plurality of second subpixel circuits SPC2 configured to drive a plurality of second light emitting devices ED2 disposed in the second display area DA2.

Referring to FIG. 7, a plurality of subpixel circuits SPC included in the subpixel circuit array SPCA may be classified into a first group GR1[1:n], a transition group GR_TRANS[1:n], and a second group GR2[1:1].

Referring to FIG. 7, the second group GR2[1:1] may include a plurality of second subpixel circuits SPC2. The second group GR2[1:1] may drive one second light emitting device ED2 disposed in the second display area DA2 in a “one-to-one (i.e., 1:1) driving method.”

Each of the plurality of second subpixel circuits SPC2 included in the second group GR2[1:1] may drive one second light emitting device ED2 disposed in the second display area DA2. That is, one second subpixel circuit SPC2 included in the second group GR2[1:1] may drive one second light emitting device ED2 disposed in the second display area DA2. Accordingly, a second anode AND2 of one second light emitting device ED2 may be connected one to one with one second subpixel circuit SPC2.

Referring to FIGS. 7 and 8, the first group GR1[1:n] may include a plurality of first subpixel circuits SPC1. The first group GR1[1:n] may drive two or more first light emitting devices ED1 disposed in the first display area DA1 in a “one-to-many driving method or a common driving method.”

Each of the plurality of first subpixel circuits SPC1 included in the first group GR1[1:n] may simultaneously drive two or more first light emitting devices ED1 disposed in the first display area DA1. That is, one first subpixel circuit SPC1 included in the first group GR1[1:n] may drive two or more first light emitting devices ED1 arranged in the first display area DAI together.

For example, as shown in FIGS. 7 and 8, one first subpixel circuit SPC1 included in the first group GR1[1:n] may drive two first light emitting devices ED1 disposed in the first display area DA1.

Referring to FIGS. 7 and 8, in order for one first subpixel circuit SPC1 disposed in the second display area DA2 to derive together two or more first light emitting devices ED1 disposed in the first display area DA1, the display panel 110 according to one or more example embodiments of the present disclosure may further include an anode extension link AEL connecting one first subpixel circuit SPC1 disposed in the second display area DA2 with two or more first light emitting devices ED1 disposed in the first display area DA1.

The anode extension link AEL may be disposed on or in the anode extension link layer 320 located between the base circuit layer 310 and the light emitting device layer 330. Accordingly, the anode extension link AEL may include a metal (i.e., an anode extension link layer metal) located between the base circuit layer 310 and the light emitting device layer 330.

Referring to FIGS. 7 and 8, some of the plurality of first subpixel circuits SPC1 included in the first group GR1[1:n] may be connected to one scan line SCL, and may receive a scan signal SC from one scan line SCL.

Referring to FIGS. 7 and 8, two or more first light emitting devices ED1 driven together by one first subpixel circuit SPC1 included in the first group GR1[1:n] may emit light of the same color.

Referring to FIGS. 7 and 8, one first subpixel circuit SPC1 included in the first group GR1[1:n] may receive a scan signal SC and a data signal VDATA, and drive two or more first light emitting devices ED1 together based on the scan signal SC and the data signal VDATA.

Referring to FIG. 7, the transition group GR_TRANS[1:] may include a plurality of transition subpixel circuits SPC2_TRANS. The transition group GR_TRANS [1:n] may also drive two or more second light emitting devices ED2 disposed in the second display area DA2 in a “one-to-many driving method or a common driving method”.

Each of the plurality of transition subpixel circuits SPC2_TRANS included in the transition group GR_TRANS[1:n] may drive two or more second light emitting devices ED2 disposed in the second display area DA2. That is, one transition subpixel circuit SPC2_TRANS included in the transition group GR_TRANS[1 n] may drive two or more second light emitting devices ED2 disposed in the second display area DA2.

Referring to FIG. 7, two or more second light emitting devices ED2 driven together by one transition subpixel circuit SPC2_TRANS according to a one-to-many driving method may be adjacent light emitting devices ED which emit light of the same color.

Since two or more second light emitting devices ED2 driven together by one transition subpixel circuit SPC2_TRANS according to a one-to-many driving method consist of the light emitting devices EDs which emit light of the same color and are arranged adjacently, two or more second light emitting devices ED2 may have similar light emitting characteristics. Therefore, the image quality through one-to-many driving may be at the same level as the image quality through one-to-one driving.

Referring to FIG. 7, in order for one transition subpixel circuit SPC2_TRANS disposed in the second display area DA2 to drive two or more second light emitting devices ED2 disposed in the second display area DA2 together, the display panel 110 according to one or more example embodiments of the present disclosure may further include a transition anode extension link AEL connecting one transition subpixel circuit SPC2_TRANS disposed in the second display area DA2 with two or more second light emitting devices ED2 disposed in the second display area DA2.

Referring to FIG. 7, the second light emitting devices ED2 driven by the transition subpixel circuits SPC2_TRANS included in the transition group GR_TRANS[1:n] may be disposed adjacent to the first light emitting devices ED1 driven by the first subpixel circuits SPC1 included in the first group GR1[1:n].

Referring to FIG. 7, the second light emitting devices ED2 driven by the transition subpixel circuits SPC2_TRANS included in the transition group GR_TRANS[1:n] may be disposed between the first light emitting devices EDI driven by the first subpixel circuits SPC1 included in the first group GR1[1:n] and the second light emitting devices ED2 driven by the second subpixel circuits SPC2 included in the second group GR2[1:1].

Referring to FIG. 7, the transition group GR_TRANS[1: n] may be disposed between the first group GR1[1:n] and the second group GR2[1:1].

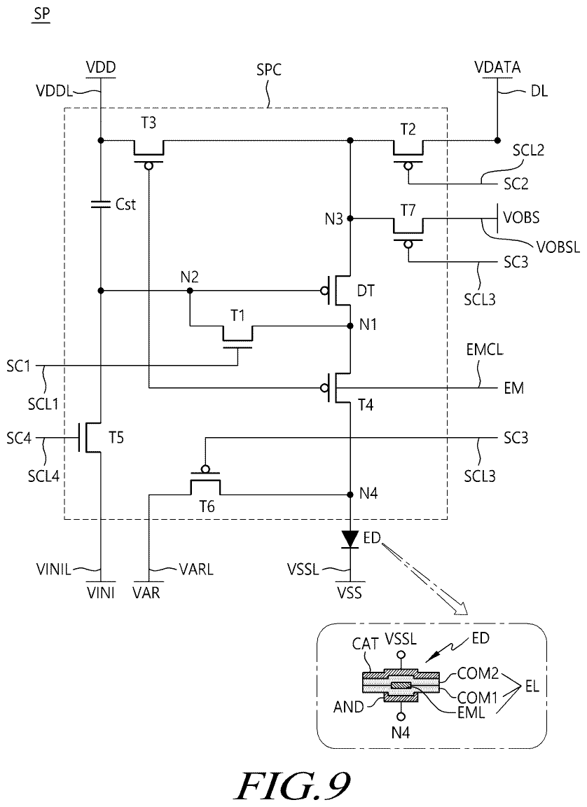

FIG. 9 is an equivalent circuit of a subpixel SP disposed on or in a display panel 110 according to one or more example embodiments of the present disclosure.

Referring to FIG. 9, a subpixel SP disposed on or in the display panel 110 according to one or more example embodiments of the present disclosure may include a light emitting device ED and a subpixel circuit SPC, and the subpixel circuit SPC may include a driving transistor DT, first to seventh transistors T1 to T7, and a storage capacitor Cst.

The subpixel circuit SPC of the subpixel SP may include a first node N1, a second node N2, a third node N3, and a fourth node N4.

The light emitting device ED may include an anode AND, a device intermediate layer EL and a cathode CAT. The device intermediate layer EL may include a first common layer COM1, an emission layer EML and a second common layer COM2.

The anode AND of the light emitting device ED may correspond to the fourth node N4.

The cathode CAT of the light emitting device ED may be electrically connected to a base voltage line VSSL. A base voltage VSS may be applied to the base voltage line VSSL. The base voltage line VSSL may also be referred to as a second driving voltage line, and the base voltage VSS may also be referred to as a second driving voltage.

A driving transistor DT may include a source node, a drain node, and a gate node. The first node N1 may be a drain node or a source node of the driving transistor DT, the second node N2 may be a gate node of the driving transistor DT, and the third node N3 may be a source node or a drain node of the driving transistor DT.

A first transistor T1 may be connected between the first node N1 and the second node N2. The first transistor T1 may be turned on or off by the first scan signal SC1 supplied from the first scan line SCL1, thereby controlling a connection between the first node N1 and the second node N2.

A second transistor T2 may be connected between the third node N3 and the data line DL. The second transistor T2 may be turned on or off by the second scan signal SC2 supplied from the second scan line SCL2, and may control a connection between the third node N3 of the driving transistor DT and the data line DL.

A third transistor T3 may be connected between the third node N3 and a first driving voltage line VDDL to which the first driving voltage VDD is applied. The third transistor T3 may be turned on or off by an emission control signal EM supplied from an emission control line EMCL, and may control a connection between the third node N3 and the first driving voltage line VDDL.

A fourth transistor T4 may be connected between the first node N1 and the fourth node N4 corresponding to the anode AND of the light emitting device ED. The fourth transistor T4 may be turned on or off by the emission control signal EM supplied from the emission control line EMCL, and may control a connection between the first node N1 and the fourth node N4.

A fifth transistor T5 may be connected between the second node N2 and an initialization voltage line VINIL to which an initialization voltage VINI is applied. The fifth transistor T5 may be turned on or off by a fourth scan signal SC4 supplied from the fourth scan line SCL4, and may control a connection between the second node N2 and the initialization voltage line VINIL.

A sixth transistor T6 may be connected between the fourth node N4 corresponding to the anode AND of the light emitting device ED and an anode reset voltage line VARL to which an anode reset voltage VAR is applied. The sixth transistor T6 may be turned on or turned off by a third scan signal SC3 supplied from a third scan line SCL3, and may control a connection between the fourth node N4 and the anode reset voltage line VARL to which the anode reset voltage VAR is applied.

A seventh transistor T7 may be connected between the third node N3 and a bias voltage line VOBSL to which a bias voltage VOBS is applied. The seventh transistor T7 may be turned on or off by the third scan signal SC3 supplied from the third scan line SCL3, and may control a connection between the third node N3 and the bias voltage line VOBSL to which the bias voltage VOBS is applied.

Each of the driving transistors DT and the first to seventh transistors T1 to T7 may be an n-type transistor or a p-type transistor.

For example, as shown in FIG. 9, the first transistor T1 and the fifth transistor T5 may be n-type transistors, and the driving transistor DT, the second transistor T2, and the third transistor T3, the fourth transistor T4, the sixth transistor T6 and the seventh transistor T7 may be p-type transistors.

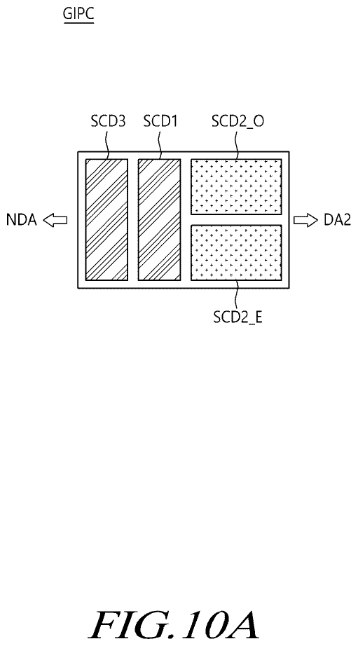

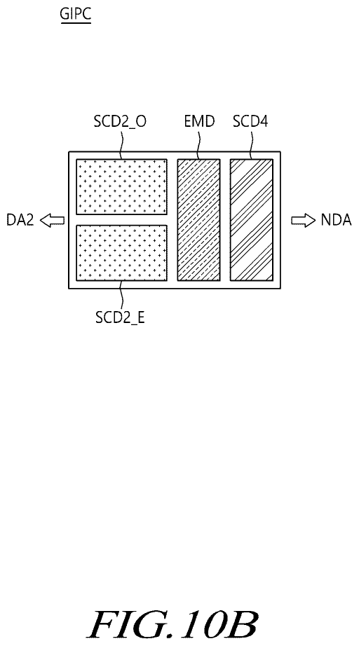

FIGS. 10A and 10B illustrate a gate-in-panel circuit GIPC disposed on or in the display panel 110 according to one or more example embodiments of the present disclosure. However, FIGS. 10A and 10B illustrate a gate-in-panel circuit GIPC when each subpixel SP disposed on or in the display panel 110 according to one or more example embodiments of the present disclosure is as shown in FIG. 9.

Referring to FIG. 10A, the gate-in-panel circuit GIPC disposed in the first display area DAI located on one side of the second display area DA2 may include a first scan driving circuit SCD1 configured to generate a first scan signal SC1 and output to a first scan line SCL1, a second scan driving circuit SCD2_O configured to generate a second scan signal SC2 and output to an odd-numbered second scan line SCL2, a second scan driving circuit SCD2_E configured to generate a second scan signal SC2 and output to an even second scan line SCL2, and a third scan driving circuit SCD3 configured to generate a third scan signal SC3 and output to the third scan line SCL3.

Referring to FIG. 10A, among the first scan driving circuit SCD1, the second scan driving circuit SCD2_O and SCD2_E, and the third scan driving circuit SCD3, the second scan driving circuit SCD2_O and SCD2_E may be disposed closest to the second display area DA2, and the third scan driving circuit SCD3 may be disposed closest to the non-display area NDA.

Referring to FIG. 10B, a gate-in-panel circuit GIPC disposed in the first display area DA1 located on the other side of the second display area DA2 may include a second scan driving circuit SCD2_O configured to generate a second scan signal SC2 and output to an odd-numbered second scan line SCL2, a second scan driving circuit SCD2_E configured to generate a second scan signal SC2 and output to an even second scan line SCL2, a fourth scan driving circuit SCD4 configured to generate a fourth scan signal SC4 and output to a fourth scan line SCL4, and an emission control circuit EMD configured to generate an emission control signal EM and output to an emission control line EMCL.

Referring to FIG. 10B, among the second scan driving circuits SCD2_O and SCD2_E, the emission control circuit EMD and the fourth scan driving circuit SCD4, the second scan driving circuits SCD2_O and SCD2_E may be located closest to the second display area DA2, and the fourth scan driving circuit SCD4 may be located closest to the non-display area NDA.

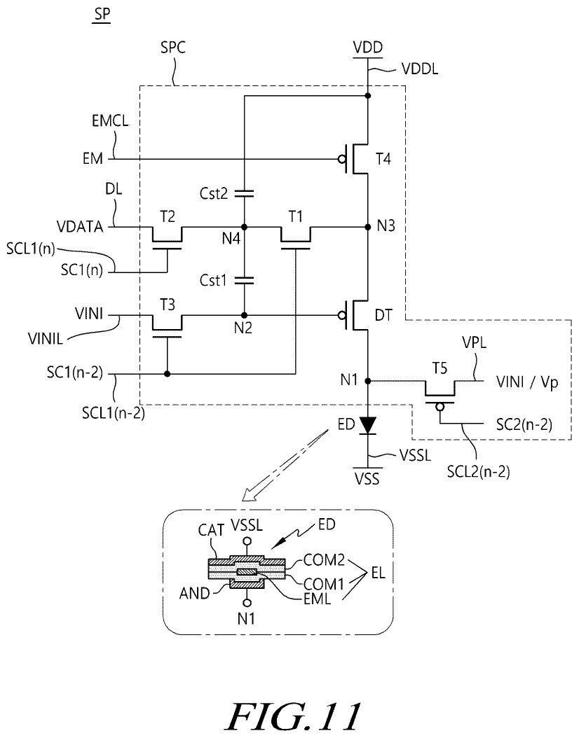

FIG. 11 is an equivalent circuit of a subpixel SP disposed on or in a display panel 110 according to one or more example embodiments of the present disclosure.

Referring to FIG. 11, the subpixel SP disposed on or in the display panel 110 according to one or more example embodiments of the present disclosure may include a light emitting device ED and a subpixel circuit SPC, and the subpixel circuit SPC may include a driving transistor DT, first to fifth transistors T1 to T5, a first storage capacitor Cst1, and a second storage capacitor Cst2.

The subpixel circuit SPC of the subpixel SP may include a first node N1, a second node N2, a third node N3, and a fourth node N4.

The light emitting device ED may include an anode AND, a device intermediate layer EL and a cathode CAT. The device intermediate layer EL may include a first common layer COM1, an emission layer EML, and a second common layer COM2.

The anode AND of the light emitting device ED may correspond to the first node N1.

The cathode CAT of the light emitting device ED may be electrically connected to the base voltage line VSSL. A base voltage VSS may be applied to the base voltage line VSSL. The base voltage line VSSL may also be referred to as a second driving voltage line, and the base voltage VSS may be referred to as a second driving voltage.

The driving transistor DT may include a source node, a drain node, and a gate node. The first node N1 may be a drain node or a source node of the driving transistor DT, the second node N2 may be a gate node of the driving transistor DT, and the third node N3 may be a source node or a drain node of the driving transistor DT.

The first transistor T1 may be connected between the third node N3 and the fourth node N4. The first transistor T1 may be turned on or off by the first scan signal SC1 (n−2) of the previous stage supplied from the first scan line SCL1 (n−2) of the previous stage, may control a connection between the third node N3 and the fourth node N4.

The second transistor T2 may be connected between the fourth node N4 and the data line DL. The second transistor T2 may be turned on or turned off by the first scan signal SC1(n) supplied from the first scan line SCL1(n), and may control a connection between the fourth node N4 and the data line DL.

The third transistor T3 may be connected between the second node N2 and an initialization voltage line VINIL to which the initialization voltage VINI is applied. The third transistor T3 may be turned on or turned off by the first scan signal SC1 (n−2) of the previous stage supplied from the first scan line SCL1 (n−2) of the previous stage, and may control a connection between the second node N2 and the initialization voltage line VINIL to which the initialization voltage VINI is applied.

The fourth transistor T4 may be connected between the third node N3 and the first driving voltage line VDDL to which the first driving voltage VDD is applied. The fourth transistor T4 may be turned on or off by an emission control signal EM supplied from an emission control line EMCL, and may control a connection between the third node N3 and the first driving voltage line VDDL.

The fifth transistor T5 may be connected between the first node N1 and the power line VPL. The fifth transistor T5 may be turned on or turned off by the second scan signal SC2(n−2) supplied from the second scan line SCL2(n−2), and may control a connection between the first node N1 and a power line VPL. Here, an initialization voltage VINI or a parking voltage Vp may be applied to the power line VPL.

Each of the driving transistors DT and the first to fifth transistors T1 to T5 may be an n-type transistor or a p-type transistor. For example, the driving transistor DT, the fourth transistor T4, and the fifth transistor T5 may be a p-type transistor, and the first transistor T1, the second transistor T2, and the third transistor T3 may be an n-type transistor.

The first storage capacitor Cst1 may be connected between the second node N2 and the fourth node N4. The second storage capacitor Cst2 may be connected between the fourth node N4 and the first driving voltage line VDDL.

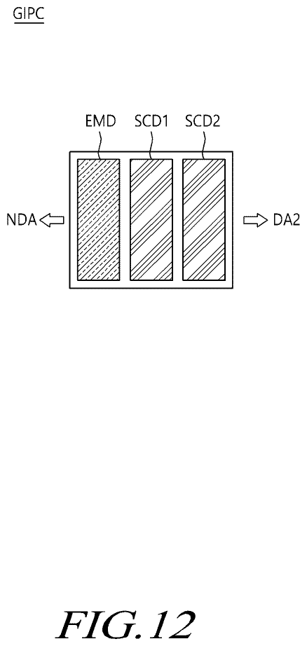

FIG. 12 illustrates a gate-in-panel circuit GIPC disposed on or in the display panel 110 according to one or more example embodiments of the present disclosure.

Referring to FIG. 12, the gate-in-panel circuit GIPC disposed in the first display area DA1 may include a first scan driving circuit SCD1 configured to generate a first scan signal SC1 and output to a first scan line SCL1, a second scan driving circuit SCD2 configured to generate a second scan signal SC2 and output to a second scan line SCL2, and an emission control circuit EMD configured to generate an emission control signal EM and output to an emission control line EMCL.

Referring to FIG. 12, among the first scan driving circuit SCD1, the second scan driving circuit SCD2, and the emission control circuit EMD, the second scan driving circuit SCD2 may be disposed closest to the second display area DA2, and the emission control circuit EMD may be disposed closest to the non-display area NDA.

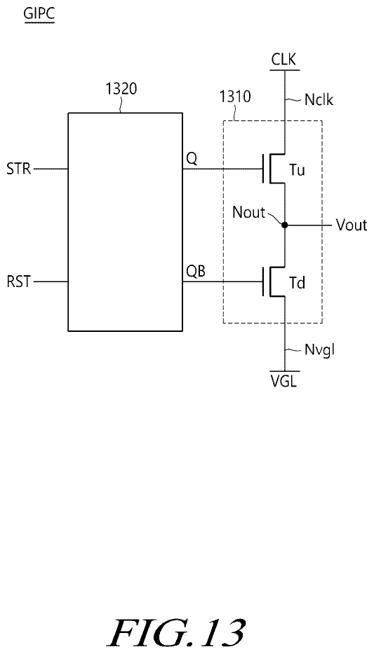

FIG. 13 illustrates a gate-in-panel circuit GIPC disposed on or in a display panel 110 according to one or more example embodiments of the present disclosure.

Referring to FIG. 13, a gate-in-panel circuit GIPC disposed on or in the display panel 110 according to one or more example embodiments of the present disclosure may include an output buffer 1310 and a control circuit 1320.

The output buffer 1310 may include a pull-up transistor Tu connected between a clock node Nclk where a clock signal CLK is input and an output node Nout outputting a gate signal Vout, and a pull-down transistor Td connected between the output node Nout outputting a gate signal Vout and a low voltage node Nvgl where a second gate voltage VGL is input.

In the case that the subpixel SP is as shown in FIG. 9, the gate signal Vout may be one of the first scan signal SC1, the second scan signal SC2, the third scan signal SC3, the fourth scan signal SC4, and the emission control signal EM. In this case, the output node Nout may be one of the first scan line SCL1, the second scan line SCL2, the third scan line SCL3, the fourth scan line SCLA, and the emission control line EMCL.

When the subpixel SP is as shown in FIG. 11, the gate signal Vout may be one of the first scan signal SC1(n), the second scan signal SC2 (n−2) and the emission control signals EM. In this case, the output node Nout may be one of the first scan line SCL1(n), the second scan line SCL2(n−2), and the emission control line EMCL.

A gate node of the pull-up transistor Tu may correspond to Q node. Depending on the voltage level of the Q node, the pull-up transistor Tu may be turned on or off.

A gate node of the pull-down transistor Td may correspond to a QB node. Depending on the voltage level of the QB node, the pull-down transistor Td may be turned on or turned off.

The voltage level of the Q node and the voltage level of the QB node may be opposite to each other. That is, when the voltage level of the Q node is a high level, the voltage level of the QB node may be a low level. When the voltage level of the Q node is a low level, the voltage level of the QB node may be a high level.

As the voltage level of the Q node and the voltage level of the QB node are opposite to each other, the on-off state of the pull-up transistor Tu and the on-off state of the pull-down transistor Td may be different. That is, when the pull-up transistor Tu is turned on, the pull-down transistor Td may be turned off. When the pull-up transistor Tu is turned off, the pull-down transistor Td may be turned on.

The control circuit 1320 may receive control signals such as a start signal STR and a reset signal RST, and control the voltage level of the Q node and the voltage level of the QB node.

The control circuit 1320 may include a plurality of transistors.

When the voltage level of the Q node becomes a high level and the voltage level of the QB node becomes a low level by the control circuit 1320, the pull-up transistor Tu may be turned on, and a gate signal Vout having a high level voltage of the clock signal CLK may be output to the output node Nout.

When the voltage level of the Q node becomes a low level and the voltage level of the QB node becomes a high level by the control circuit 1320, the pull-down transistor Td may be turned on, and a gate signal Vout having a second gate voltage VGL corresponding to a low level voltage may be output to the output node Nout.

The transistors Tu and Td included in the output buffer 1310, and a plurality of transistors included in the control circuit 1320 may be referred to as gate driving transistors.

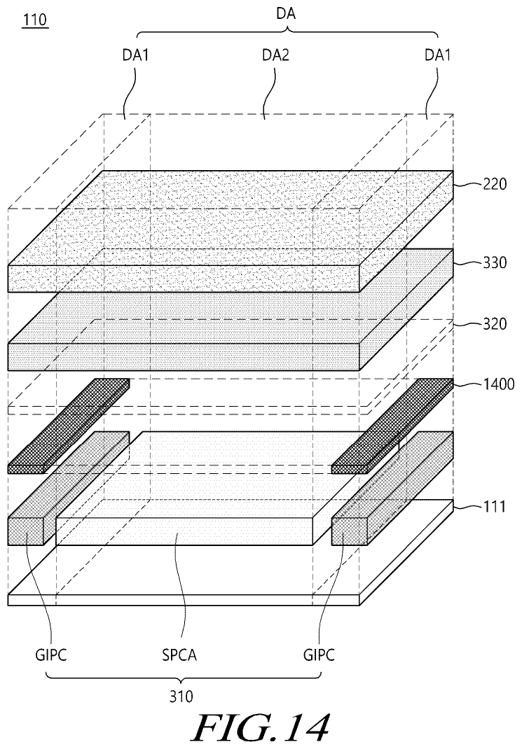

FIG. 14 illustrates a vertical structure of a display panel 110 according to one or more example embodiments of the present disclosure.

Referring to FIG. 14, the display panel 110 according to one or more example embodiments of the present disclosure may include a shielding layer 1400 disposed between a gate-in-panel circuit GIPC included in the base circuit layer 310 and the light emitting device layer 330.

Referring to FIG. 14, the display panel 110 according to one or more example embodiments of the present disclosure may further include an anode extension link AEL connecting one first subpixel circuit SPC1 to two or more anodes AND, which are two or more pixel electrodes included in two or more first light emitting devices ED1.

Referring to FIG. 14, the shielding layer 1400 may be disposed in the first display area DA1, and may be disposed between the gate-in-panel circuit GIPC and an anode extension link layer 320 where the anode extension link AEL is disposed.

At least a portion of the shielding layer 1400 may overlap with the anode extension link AEL and the gate-in-panel circuit GIPC. Accordingly, the anode extension link AEL and the gate-in-panel circuit GIPC electrically connected to the anode AND may not have an unnecessary electrical effect on each other, thereby improving the image quality.

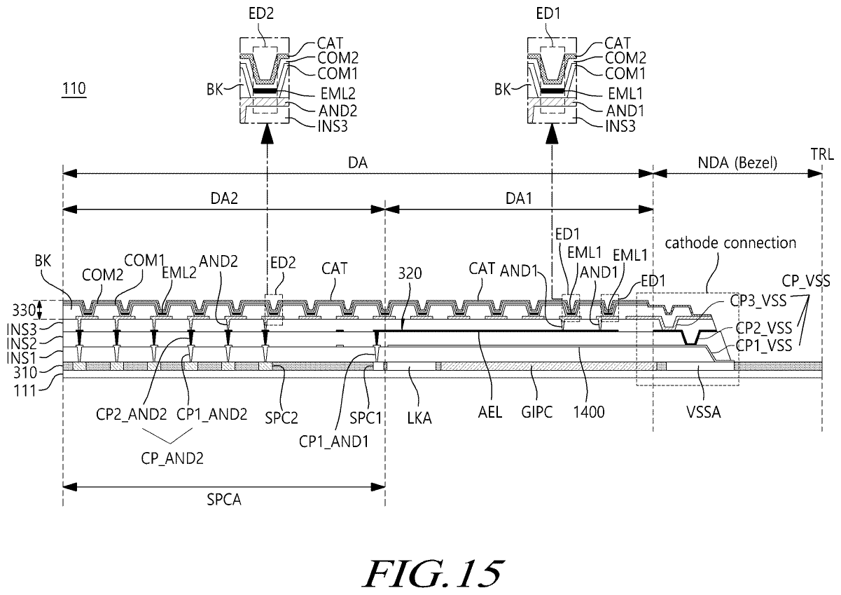

FIG. 15 is a cross-sectional view illustrating a vertical structure of a display panel 110 according to one or more example embodiments of the present disclosure.

Referring to FIG. 15, the display panel 110 according to one or more example embodiments of the present disclosure may include a display area DA and a non-display area NDA. The display area DA may include a first display area DA1 and a second display area DA2. The first display area DA1 may be located between the second display area DA2 and the non-display area NDA.

Referring to FIG. 15, the display panel 110 according to one or more example embodiments of the present disclosure may include a substrate 111, a base circuit layer 310 on the substrate 111, and a light emitting device layer 330 on the base circuit layer 310.

The display panel 110 according to one or more example embodiments of the present disclosure may further include at least one insulating layer disposed between the base circuit layer 310 and the light emitting device layer 330.

For example, as shown in FIG. 15, the first to third insulating layers INS1, INS2 and INS3 may be disposed between the base circuit layer 310 and the light emitting device layer 330. For example, the first insulating layer INS1 may be an inorganic layer or an organic layer. The second insulating layer INS2 and the third insulating layer INS3 may function as a planarization layer and may be an organic layer.

Referring to FIG. 15, a subpixel circuit array SPCA, a link area LKA, a gate-in-panel circuit GIPC and a base voltage line area VSSA may be disposed in the base circuit layer 310.

The subpixel circuit array SPCA may be disposed in the second display area DA2, the link area LKA may be disposed in the first display area DA1, the gate-in-panel circuit GIPC may be placed in the first display area DA1, and the base voltage line area VSSA may be placed in the non-display area NDA.

Referring to FIG. 15, a plurality of light emitting devices ED may be disposed in the light emitting device layer 330. The plurality of light emitting devices ED disposed in the light emitting device layer 330 may include a plurality of first light emitting devices ED1 disposed in the first display area DA1 and a plurality of second light emitting devices ED2 disposed in the second display area DA2.

The two or more first light emitting devices ED1 disposed in the first display area DA1 may be driven in a one-to-many driving method (i.e., common driving method) by at least one first subpixel circuit SPC1 among the plurality of subpixel circuits SPC included in the subpixel circuit array SPCA.

Most of the plurality of second light emitting devices ED2 disposed in the second display area DA2 may be driven in a one-to-one driving manner by the second subpixel circuits SPC2 among the plurality of subpixel circuits SPC included in the subpixel circuit array SPCA.

Some of the plurality of second light emitting devices ED2 disposed in the second display area DA2 may be driven in a common driving manner by transition subpixel circuits SPC2_TRANS among the plurality of subpixel circuits SPC included in the subpixel circuit array SPCA (see FIG. 7).

Referring to FIG. 15, the light emitting device layer 330 may include two or more first anodes AND1 disposed in the first display area DA1 and two or more first emission layers EML1 disposed in the first display area DA1 and each located on two or more first anodes AND1.

Referring to FIG. 15, the light emitting device layer 330 may include two or more second anodes AND2 disposed in the second display area DA2 and two or more second emission layers EML2 disposed in the second display area DA2 and each located on two or more second anodes AND2.

Referring to FIG. 15, the light emitting device layer 330 may include a cathode CAT disposed across the first display area DA1 and the second display area DA2 and disposed on two or more first emission layers EML1 and two or more second emission layers EML2.

Referring to FIG. 15, two or more first light emitting devices ED1 may be formed in the first display area DA1 by two or more first anodes AND1, two or more first emission layers EML1 and cathodes CAT.

Referring to FIG. 15, two or more second light emitting devices ED2 may be formed in the second display area DA2 by two or more second anodes AND2, two or more second emission layers EML2, and cathodes CAT.

Referring to FIG. 15, the first common layer COM1 and the second common layer COM2 may be disposed over the entire display area DA. The first common layer COM1 may be disposed between the anodes AND1 and AND2 and the emission layers EML1 and EML2, and may be disposed over the entire display area DA. The second common layer COM2 may be disposed between the emission layers EML1 and EML2 and the cathode CAT, and may be disposed throughout the display area DA.

Referring to FIG. 15, in the display area DA, the emission areas of the light emitting deices ED1 and ED2 may be defined by the openings of the bank BK. The bank BK may be located on the anodes AND1 and AND2, and may have openings which expose a portion of the anodes AND1 and AND2. The openings of the bank BK may be the emission areas. The bank BK may also be referred to as a light emitting unit defining layer.

Referring to FIG. 15, the display panel 110 according to one or more example embodiments of the present disclosure may include a connection metal structure for connection between the base circuit layer 310 and the light emitting device layer 330.

Referring to FIG. 15, the connecting metal structure of the display panel 110 according to one or more example embodiments of the present disclosure may include a first metal layer disposed between the first insulating layer INS1 and the second insulating layer INS2, a second metal layer disposed between the second insulating layer INS2 and a third insulating layer INS3, and a third metal layer disposed between the third insulating layer INS3 and the light emitting device layer 330.

Referring to FIG. 15, the display panel 110 according to one or more example embodiments of the present disclosure may include a second anode connection structure electrically connecting the second anode AND2 disposed in the light emitting device layer 330 and the second subpixel circuit SPC2 disposed in the base circuit layer 310 on a one-to-one basis.

Referring to FIG. 15, the second anode connection structure of the display panel 110 according to one or more example embodiments of the present disclosure may include a second anode connection pattern CP_AND2. Each of the two or more second anodes AND2 may be electrically connected to the second subpixel circuit SPC2 disposed in the base circuit layer 310 through the second anode connection pattern CP_AND2.

Referring to FIG. 15, the second anode connection pattern CP_AND2 may include a second metal connection pattern CP2_AND2 and a first metal connection pattern CP1_AND2.

Referring to FIG. 15, two or more second anodes AND2 may be disposed in a third metal layer. One second anode AND2 may be electrically connected to the second metal connection pattern CP2_AND2 located in a second metal layer through a hole in the third insulating layer INS3, the second metal connection pattern CP2_AND2 may be electrically connected to the first metal connection pattern CP1_AND2 located in a first metal layer through a hole in the second insulating layer INS2, and the first metal connection pattern CP1_AND2 may be electrically connected to the second subpixel circuit SPC2 disposed in the base circuit layer 310 through a hole in the first insulating layer INS1.

Referring to FIG. 15, two or more first anodes AND1 may be electrically connected to the first subpixel circuit SPC1 disposed in the base circuit layer 310 through the anode extension link AEL disposed in the anode extension link layer 320.

Referring to FIG. 15, the display panel 110 according to one or more example embodiments of the present disclosure may include a first anode connection structure electrically connecting two or more first anodes AND1 disposed in the light emitting device layer 330 and the first subpixel circuit SPC1 disposed in the base circuit layer 310.

Referring to FIG. 15, the first anode connection structure of the display panel 110 according to one or more example embodiments of the present disclosure may include an anode extension link AEL and an anode connection pattern CP_AND1.

Referring to FIG. 15, two or more first anodes AND1 may be disposed in the third metal layer. The anode extension link layer 320 may be a second metal layer on the second insulating layer INS2. The anode connection pattern CP_AND1 may include a first metal connection pattern CP1_AND1 located in the first metal layer on the first insulating layer INS1.

Referring to FIG. 15, in the first display area DA1, each of the two or more first anodes AND1 may be electrically connected to one anode extension link AEL located in the second metal layer through a hole in the third insulating layer INS3. Here, the second metal layer may be an anode extension link layer 320.

Referring to FIG. 15, the anode extension link AEL may be electrically connected to the first metal connection pattern CP1_AND1 located in the first metal layer through a hole in the second insulating layer INS2, and the first metal connection pattern CP1_AND1 may be electrically connected to the first subpixel circuit SPC1 disposed in the base circuit layer 310 through a hole in the first insulating layer INS1.

Referring to FIG. 15, the anode extension link AEL may include first part electrically connected to two or more first anodes AND1 located in the light emitting device layer 330 in the first display area DA1, and a second part connected to the first subpixel circuit SPC1 located in the base circuit layer 310 in the second display area DA2. Here, the first part may be located in the first display area DA1, and the second part may be located in the second display area DA2.

Referring to FIG. 15, the anode extension link AEL may be disposed to extend from the first display area DA1 to the second display area DA2 in a planar manner. A first anode connection structure including the anode extension link AEL may be located from the base circuit layer 310 to the light emitting device layer 330 in a vertical direction.

Referring to FIG. 15, in the base circuit layer 310, the link area LKA may be located between the subpixel circuit array SPCA and the gate-in-panel circuit GIPC.

Referring to FIG. 15, in the base circuit layer 310, a base voltage line area VSSA may exist outside the gate-in-panel circuit GIPC. A base voltage line VSSL to which the base voltage VSS is applied may be disposed in the base voltage line area VSSA.

Referring to FIG. 15, the display panel 110 according to one or more example embodiments of the present disclosure may include a cathode connection structure to electrically connect the cathode CAT and the base voltage line VSSL.

Referring to FIG. 15, the cathode connection structure of the display panel 110 according to one or more example embodiments of the present disclosure may include a cathode connection pattern CP_VSS. The cathode connection pattern CP_VSS may include a first cathode connection pattern CP1_VSS, a second cathode connection pattern CP2_VSS, and a third cathode connection pattern CP3_VSS.

Referring to FIG. 15, the first cathode connection pattern CP1_VSS may be located in the first metal layer on the first insulating layer INS1.

The second cathode connection pattern CP2_VSS may be located in the second metal layer on the second insulating layer INS2. Here, the second metal layer may be an anode extension link layer 320 on which an anode extension link AEL is disposed.

The third cathode connection pattern CP3_VSS may be located in the third metal layer on the third insulating layer INS3. Here, the third metal layer may be a metal layer where the anodes AND1 and AND2 are disposed.

Referring to FIG. 15, the cathode CAT may be electrically connected to the third cathode connection pattern CP3_VSS through a hole in the bank BK, the third cathode connection pattern CP3_VSS may be electrically connected to the second cathode connection pattern CP2_VSS through a hole in the third insulating layer INS3, the second cathode connection pattern CP2_VSS may be electrically connected to the first cathode connection pattern CP1_VSS through a hole in the second insulating layer INS2, and the first cathode connection pattern CP1_VSS may be electrically connected to the base voltage line VSSL through a hole in the first insulating layer INS1.

Referring to FIG. 15, the first cathode connection pattern CP1_VSS may be disposed in the same first metal layer as the shielding layer 1400, and may be electrically connected to the shielding layer 1400 or may be configured integrally with the shielding layer 1400.

Referring to FIG. 15, the base voltage line VSSL and the cathode connection pattern CP_VSS may be located in the non-display area NDA. The base voltage line VSSL may be disposed in the base voltage line area VSSA located outside the gate-in-panel circuit GIPC.

Referring to FIG. 15, the shielding layer 1400 may be located between the gate-in-panel circuit GIPC included in the base circuit layer 310 and the light emitting device layer 330.

The shielding layer 1400 may be disposed in the first display area DA1.

The shielding layer 1400 may be electrically connected to the cathode connection pattern CP_VSS. Accordingly, the base voltage VSS applied to the cathode CAT of the light emitting devices ED1 and ED2 may be applied to the shielding layer 1400.

The shielding layer 1400 may be disposed in the first display area DA1, and may be located between the gate-in-panel circuit GIPC and the anode extension link AEL. The shielding layer 1400 may overlap with the gate-in-panel circuit GIPC and the anode extension link AEL.

Accordingly, the anode extension link AEL may not be electrically affected by the gate-in-panel circuit GIPC. The gate-in-panel circuit GIPC may not be electrically affected by the anode extension link AEL.

Referring to FIG. 15, the display panel 110 according to one or more example embodiments of the present disclosure may include a substrate 111 including a display area DA with a first display area DA1 and a second display area DA2 and a non-display area NDA outside the display area DA, two or more first light emitting devices ED1 disposed in the first display area DA1, two or more second light emitting devices ED2 disposed in the second display area DA2, one first subpixel circuit SPC1 commonly connected to two or more first light emitting devices ED1, and two or more second subpixel circuits SPC2 each connected to two or more second light emitting devices ED2, respectively.

Referring to FIG. 15, the display panel 110 according to one or more example embodiments of the present disclosure may further include a gate-in-panel circuit GIPC disposed in the first display area DA1.

Referring to FIG. 15, the display panel 110 according to one or more example embodiments of the present disclosure may further include an extension link AEL electrically connecting two or more first light emitting devices ED1 and one first subpixel circuit SPC1.

Referring to FIG. 15, the display panel 110 according to one or more example embodiments of the present disclosure may further include a shielding layer 1400 disposed between the gate-in-panel circuit GIPC and the extension link AEL.

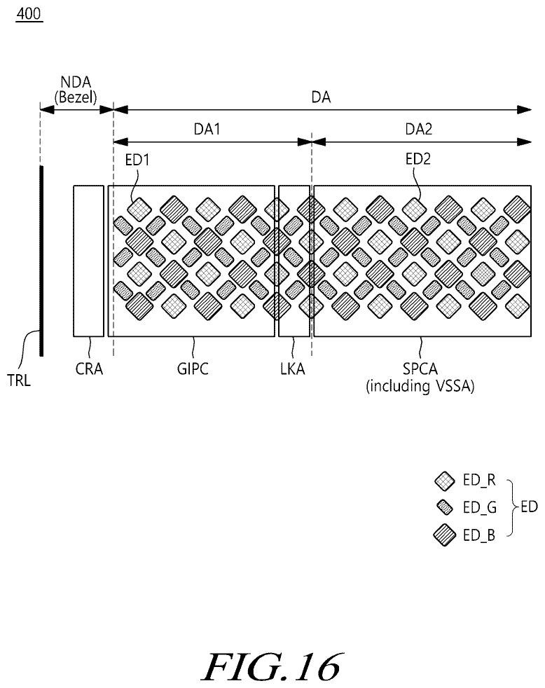

FIG. 16 is another plan view of a partial area of a display panel 110 according to one or more example embodiments of the present disclosure.

Referring to FIG. 16, the display panel 110 may include a display area DA and a non-display area NDA1, and the display area DA may include a first display area DA1 and a second display area DA2. The non-display area NDA may also be referred to as a bezel.

Referring to FIG. 16, the first display area DA1 may be located between the non-display area NDA and the second display area DA2.

Referring to FIG. 16, the display area DA may include a plurality of light emitting devices ED. For example, the plurality of light emitting devices ED may include a red light emitting device ED_R for emitting red light, a green light emitting device ED_G for emitting green light, and a blue light emitting device ED_B for emitting blue light.

Referring to FIG. 16, the plurality of light emitting devices ED1 disposed in the display area DA may include a plurality of first light emitting devices ED1 disposed in the first display area DA1, and a plurality of second light emitting devices ED2 disposed in the second display area DA2.

Referring to FIG. 16, a subpixel circuit array SPCA may be disposed in the second display area DA2. The subpixel circuit array SPCA may include a plurality of subpixel circuits SPC.

The plurality of subpixel circuits SPC may include at least one first subpixel circuit SPC for driving a plurality of first light emitting devices ED1 disposed in the first display area DA1, and a plurality of second subpixel circuits SPC for driving a plurality of second light emitting devices ED2 disposed in the second display area DA2.

Referring to FIG. 16, all or part of the gate-in-panel circuit GIPC may be disposed in the first display area DA1.

Referring to FIG. 16, the display panel 110 according to one or more example embodiments of the present disclosure may include a link area LKA where links are disposed to transmit various gate signals output from the gate-in-panel circuit GIPC to the subpixel circuit array SPCA.

For example, the links disposed in the link area LKA may electrically connect output points of the gate-in-panel circuit GIPC and the gate lines GL. In the case that the output points of the gate-in-panel circuit GIPC are a first metal layer and the gate line GL is a second metal layer different from the first metal layer, the links may include a jumping metal connecting the first metal layer and the second metal layer to each other.

Referring to FIG. 16, the link area LKA may be located between the gate-in-panel circuit GIPC and the subpixel circuit array SPCA.

The link area LKA may be included in the first display area DA1.

Referring to FIG. 16, the display panel 110 according to one or more example embodiments of the present disclosure may include a crack management area CRA in which a crack detection line and/or a crack stopper pattern is disposed.

For example, the crack management area CRA may be included in the non-display area NDA. In this case, the crack detection line and/or the crack stopper pattern may not overlap with the first light emitting device ED1 disposed in the first display area DA1.

As another example, the crack management area CRA may be included in the first display area DA1. In this case, the crack detection line and/or the crack stopper pattern may overlap the first light emitting device ED1 disposed in the first display area DA1.

Referring to FIG. 16, in the display panel 110 according to one or more example embodiments of the present disclosure, the base voltage line VSSL may be disposed in the display area DA. For example, the base voltage line VSSL may be disposed in at least one of the first display area DA1 and the second display area DA2 included in the display area DA. Accordingly, the cathode CAT may be electrically connected to the base voltage line VSSL disposed on at least one of the first display area DA1 and the second display area DA2 included in the display area DA.

Accordingly, the base voltage line area VSSA may not exist in the non-display area NDA. Accordingly, the bezel, which is the non-display area NDA, may become smaller.

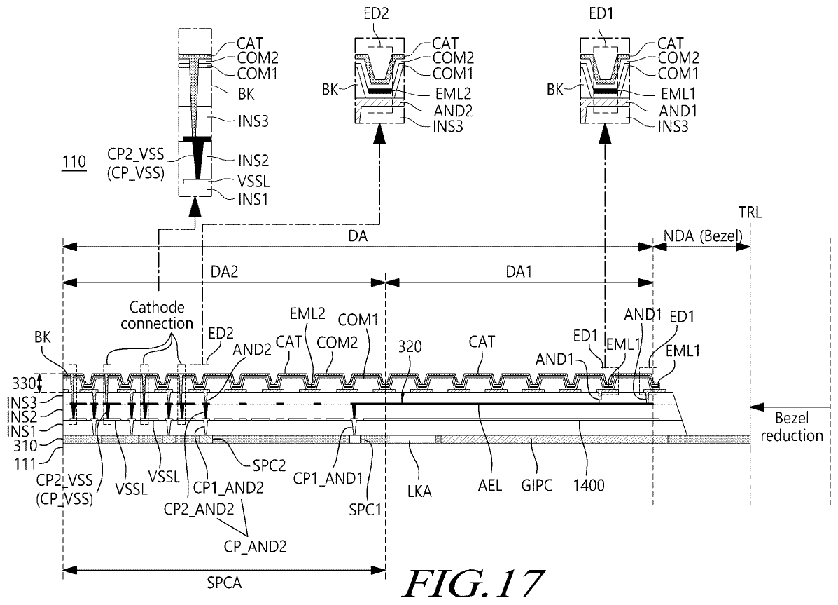

FIG. 17 is another cross-sectional view illustrating the vertical structure of the display panel 110 according to one or more example embodiments of the present disclosure. In the following description, differences from FIG. 15 will be mainly explained, and repetitive descriptions may be omitted for brevity.

Referring to FIG. 17, in the display panel 110 according to one or more example embodiments of the present disclosure, the base voltage line VSSL may be located in the display area DA. The display panel 110 according to one or more example embodiments of the present disclosure may include a cathode connection structure that electrically connects the cathode CAT and base voltage line VSSL, and the cathode connection structure may be located in the display area DA.

For example, the base voltage line VSSL may be disposed in at least one of the first display area DA1 and the second display area DA2 included in the display area DA. Accordingly, the cathode CAT may be electrically connected to the base voltage line VSSL through a cathode connection structure located in at least one of the first display area DA1 and the second display area DA2 included in the display area DA.

Referring to FIG. 17, a cathode connection pattern CP_VSS, which is a cathode connection structure connecting the cathode CAT and the base voltage line VSSL, may be located in the display area DA. That is, the cathode connection pattern CP_VSS may be located in at least one of the first display area DA and the second display area DA2 included in the display area DA.

Referring to FIG. 17, the cathode CAT may be electrically connected to the cathode connection pattern CP_VSS located below the bank BK through a hole in the bank BK located between two or more second anodes.

Referring to FIG. 17, the base voltage line VSSL may be located in a first metal layer on the first insulating layer INS1. The cathode connection pattern CP_VSS may include a first cathode connection pattern CP2_VSS located in a second metal layer on the second insulating layer INS2.

The cathode CAT may be electrically connected to the first cathode connection pattern CP2_VSS through the through holes in the second common layer COM2, the first common layer COM1, the bank BK and the third insulating layer INS3.

The first cathode connection pattern CP2_VSS may be electrically connected to the base voltage line VSSL located on the first insulating layer INS1 through a hole in the second insulating layer INS2.

Referring to FIG. 17, through holes in the second common layer COM2, the first common layer COM1, the bank BK, and the third insulating layer INS3 may be formed through a laser drilling process.

According to the above, the base voltage line VSSL and the cathode connection pattern CP_VSS, which is a cathode connection structure, are not required to be disposed in the non-display area NDA. Accordingly, the bezel may be further reduced to the extreme.

In FIGS. 15 to 17, the display panel 110 according to one or more example embodiments of the present disclosure may include, as a connection metal structure for connection between the base circuit layer 310 and the light emitting device layer 330, three insulating layers INS1 to INS3 and three metal layers between the base circuit layer 310 and the light emitting device layer 330. Here, the three metal layers may include a first metal layer disposed between the first insulating layer INS1 and the second insulating layer INS2, a second metal layer disposed between the second insulating layer INS2 and the third insulating layer INS3, and a third metal layer disposed between the third insulating layer INS3 and the light emitting device layer 330. Here, the third metal layer may be a metal layer where the anodes AND1 and AND2 are disposed.

The display panel 110 according to one or more example embodiments of the present disclosure may include a connection metal structure different from the connection metal structure (i.e., three insulating layers and three metal layers) between the base circuit layer 310 and the light emitting device layer 330 in FIGS. 15 to 17.

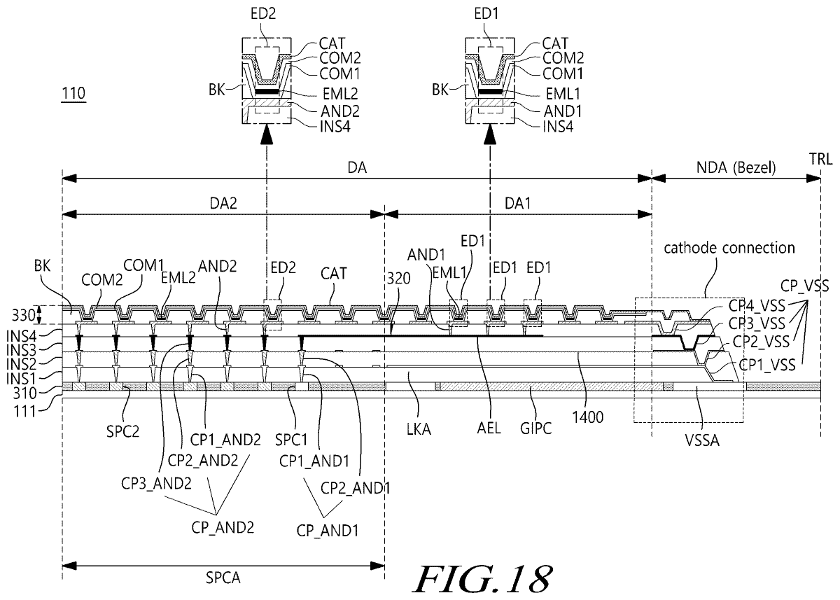

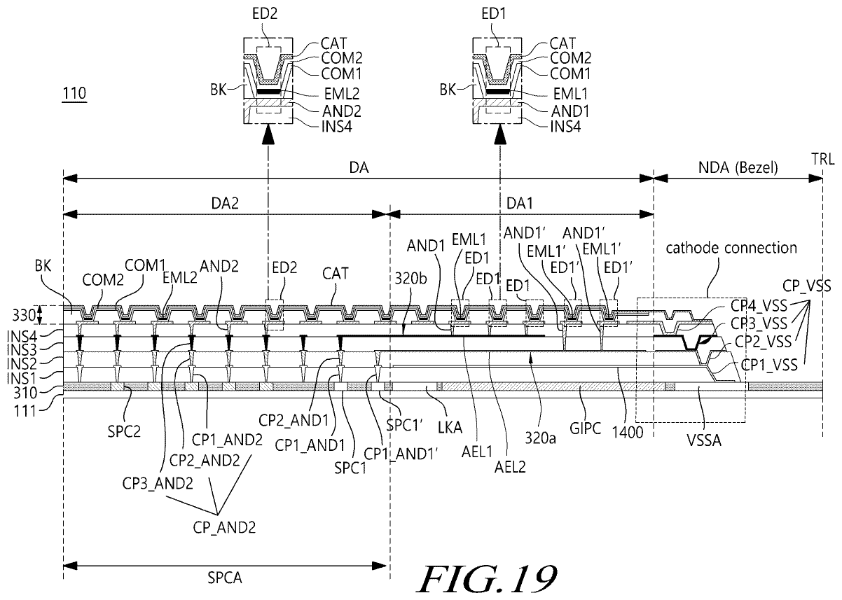

Hereinafter, other connection metal structures of the display panel 110 according to one or more example embodiments of the present disclosure will be described with reference to FIGS. 18 and 19. In the following description, differences from FIG. 15 will be mainly explained, and repetitive descriptions may be omitted for brevity.

FIG. 18 is another cross-sectional view illustrating a vertical structure of a display panel 110 according to one or more example embodiments of the present disclosure.

Referring to FIG. 18, the display panel 110 according to one or more example embodiments of the present disclosure may include, as a connection metal structure for connection between the base circuit layer 310 and the light emitting device layer 330, four insulating layers INS1 to INS4 and four metal layers between the base circuit layer 310 and the light emitting device layer 330.

Referring to FIG. 18, the four metal layers may include a first metal layer disposed between the first insulating layer INS1 and the second insulating layer INS2, a second metal layer disposed between the second insulating layer INS2 and the third insulating layer INS3, a third metal layer disposed between the third insulating layer INS3 and the fourth insulating layer INS4, and a fourth metal layer disposed between the fourth insulating layer INS4 and the light emitting device layer 330. Here, the fourth metal layer may be a metal layer where the anodes AND1 and AND2 are disposed.

Referring to FIG. 18, in the light emitting device layer 330, the second anode AND2 for configuring the second light emitting device ED2 disposed in the second display area DA2 may be disposed within the fourth metal layer on the fourth insulating layer INS4.

Referring to FIG. 18, the display panel 110 according to one or more example embodiments of the present disclosure may include a second anode connection pattern CP_AND2 as a second anode connection structure to electrically connect the second anode AND2 to the second subpixel circuit SPC2 disposed on or in the base circuit layer 310.

Referring to FIG. 18, the second anode connection pattern CP_AND2 may include a first metal connection pattern CP1_AND2, a second metal connection pattern CP2_ADN2, and a third metal connection pattern CP3_AND2.

Referring to FIG. 18, the second anode AND2 may be electrically connected to the third metal connection pattern CP3_AND2 through a hole in the fourth insulating layer INS4, the third metal connection pattern CP3_AND2 may be electrically connected to the second metal connection pattern CP2_AND2 through a hole in the third insulating layer INS3, the second metal connection pattern CP2_AND2 may be electrically connected to the first metal connection pattern CP1_AND2 through a hole in the second insulating layer INS2, and the first metal connection pattern CP1_AND2 may be electrically connected to the second subpixel circuit SPC2 through a hole in the first insulating layer INS1.

Referring to FIG. 18, the display panel 110 according to one or more example embodiments of the present disclosure may include a first anode connection structure electrically connecting two or more first anodes AND1 disposed in the light emitting device layer 330 and the first subpixel circuit SPC1 disposed in the base circuit layer 310.

Referring to FIG. 18, two or more first anodes AND1 may be electrically connected to one first subpixel circuit SPC1 disposed in the base circuit layer 310 through a first anode connection structure. In the example of FIG. 18, three first anodes AND1 may be electrically connected to one first subpixel circuit SPC1 disposed in the base circuit layer 310 through the first anode connection structure.

Referring to FIG. 18, the first anode connection structure of the display panel 110 according to one or more example embodiments of the present disclosure may include an anode extension link AEL and a first anode connection pattern CP_AND1.

Referring to FIG. 18, in the first display area DA1, two or more first anodes AND1 may be disposed in the fourth metal layer. The anode extension link layer 320 may be a third metal layer on the third insulating layer INS2.

Referring to FIG. 18, the first anode connection pattern CP_AND1 may include a first metal connection pattern CP1_AND1 located in the first metal layer on the first insulating layer INS1, and a second metal connection pattern CP2_AND1 located in the second metal layer on the second insulating layer INS2.

Referring to FIG. 18, each of the two or more first anodes AND1 may be electrically connected to one anode extension link AEL located in the third metal layer through a hole in the fourth insulating layer INS4. Here, the third metal layer on the third insulating layer INS3 may be an anode extension link layer 320.

The anode extension link AEL may be electrically connected to the second metal connection pattern CP2_AND1 located in the second metal layer through a hole in the third insulating layer INS3.

The second metal connection pattern CP2_AND1 may be electrically connected to the first metal connection pattern CP1_AND1 located in the first metal layer through a hole in the second insulating layer INS2.

The first metal connection pattern CP1_AND1 may be electrically connected to the first subpixel circuit SPC1 disposed in the base circuit layer 310 through a hole in the first insulating layer INS1.

Referring to FIG. 18, the anode extension link AEL may include a first part electrically connected to two or more first anodes AND1 located in the light emitting device layer 330 in the first display area DA1, and a second part connected to the first subpixel circuit SPC1 located in the base circuit layer 310 in the second display area DA2. Here, the first part may be located in the first display area DA1, and the second part may be located in the second display area DA2.

Referring to FIG. 18, the anode extension link AEL may be arranged to extend from the first display area DA1 to the second display area DA2 in a plane. The first anode connection structure including the anode extension link AEL may be located from the base circuit layer 310 to the light emitting device layer 330 in a vertical direction.

Referring to FIG. 18, the shielding layer 1400 may be disposed on the first insulating layer INS1, and may be disposed in a first metal layer located between the first insulating layer INS1 and the second insulating layer (INS2).

Alternatively, the shielding layer 1400 may be disposed on the second insulating layer INS2, and may be disposed in the third metal layer located between the second insulating layer INS2 and the third insulating layer INS3.

Referring to FIG. 18, in the base circuit layer 310, a base voltage line area VSSA may exist outside the gate-in-panel circuit GIPC. A base voltage line VSSL to which the base voltage VSS is applied may be disposed in the base voltage line area VSSA.

Referring to FIG. 18, the display panel 110 according to one or more example embodiments of the present disclosure may include a cathode connection structure to electrically connect the cathode CAT and the base voltage line VSSL.

Referring to FIG. 18, the cathode connection structure of the display panel 110 according to one or more example embodiments of the present disclosure may include a cathode connection pattern CP_VSS. The cathode connection pattern CP_VSS may include a first cathode connection pattern, a second cathode connection pattern, a third cathode connection pattern, and a fourth cathode connection pattern.

Referring to FIG. 18, the first cathode connection pattern may be the first cathode connection pattern CP1_VSS disposed in the first metal layer on the first insulating layer INS1. The second cathode connection pattern may be the second cathode connection pattern CP2_VSS disposed in the second metal layer on the second insulating layer INS2. The third cathode connection pattern may be a third cathode connection pattern CP3_VSS disposed in the third metal layer on the third insulating layer INS3. Here, the third metal layer may be an anode extension link layer 320 on which an anode extension link AEL is disposed. The fourth cathode connection pattern may be the fourth metal connection pattern CP4_VSS located in the fourth metal layer on the fourth insulating layer INS4. Here, the fourth metal layer may be a metal layer where the anodes AND1 and AND2 are disposed.

Referring to FIG. 18, the cathode CAT may be electrically connected to the fourth metal connection pattern CP4_VSS through a hole in the bank BK, the fourth metal connection pattern CP4_VSS may be electrically connected to the third cathode connection pattern CP3_VSS through a hole in the fourth insulating layer INS4, the third cathode connection pattern CP3_VSS may be electrically connected to the second cathode connection pattern CP2_VSS through a hole in the third insulating layer INS3, the second cathode connection pattern CP2_VSS may be electrically connected to the first cathode connection pattern CP1_VSS through a hole in the second insulating layer INS2, and the first cathode connection pattern CP1_VSS may be electrically connected to the base voltage line VSSL through a hole in the first insulating layer INS1.

Referring to FIG. 18, the first cathode connection pattern CP1_VSS may be disposed in the same first metal layer as the shielding layer 1400, and may be electrically connected to the shielding layer 1400 or may be configured integrally with the shielding layer 1400.

Referring to FIG. 18, the base voltage line VSSL and the cathode connection pattern CP_VSS may be located in the non-display area NDA. The base voltage line VSSL may be disposed in the base voltage line area VSSA located outside the gate-in-panel circuit GIPC.

FIG. 19 is another cross-sectional view illustrating a vertical structure of a display panel 110 according to one or more example embodiments of the present disclosure.

Referring to FIG. 19, the light emitting device layer 330 may further include two or more third anodes AND′ disposed in the first display area DA1, and two or more third emission layers EML1′ each located on two or more third anodes AND′.

Two or more third light emitting devices ED1′ may be formed in the first display area DA1 by two or more third anodes AND′, two or more third emission layers EML1′ and cathodes CAT.

The subpixel circuit array SPCA may be configured to simultaneously drive two or more third light emitting devices ED1′, and may further include one third subpixel circuit SPC1′ disposed in the first display area DA1.

In the display panel 110 according to one or more example embodiments of the present disclosure, the anode extension links AEL may all be disposed in the same metal layer. That is, the number of anode extension link layers 320, which are metal layers on which the anode extension links AEL are disposed, may be one.

Alternatively, in the display panel 110 according to one or more example embodiments of the present disclosure, the anode extension links AEL may be disposed in different metal layers. That is, the number of anode extension link layers 320, which are metal layers on which the anode extension links AEL are disposed, may be two or more.

According to the example of FIG. 19, the display panel 110 according to one or more example embodiments of the present disclosure may include a first anode extension link AEL1 located in a first anode extension link layer 320b, and a second anode extension link AEL2 located in a second anode extension link layer 320a.

The first anode extension link AEL1 may connect one first subpixel circuit SPC1 disposed in the second display area DA2 to two or more first light emitting devices ED1 disposed in the first display area DA1.

The second anode extension link AEL2 may connect one third subpixel circuit SPC1′ disposed in the second display area DA2 to two or more third light emitting devices ED1′ disposed in the first display area DA1.

Referring to FIG. 19, the first anode extension link AEL1 and the second anode extension link AEL2 may be located between the base circuit layer 310 and the light emitting device layer 330, and may be disposed in different metal layers.

Referring to FIG. 19, the first anode extension link AEL1 may be located in a third metal layer between the third insulating layer INS3 and the fourth insulating layer INS4. In this case, two or more first anodes AND1 may be electrically connected to the first anode extension link AEL1 through holes in the fourth insulating layer INS4.

Referring to FIG. 19, the second anode extension link AEL1′ may be located in a second metal layer between the second insulating layer INS2 and the third insulating layer INS3. In this case, two or more third anodes AND1′ may be electrically connected to the second anode extension link AEL1′ through holes in the fourth insulating layer INS4 and the third insulating layer INS3.

Referring to FIG. 19, a cathode connection pattern CP_VSS may include a first cathode connection pattern CP1_VSS disposed on the first metal layer, a second cathode connection pattern CP2_VSS disposed on the same second metal layer as the second anode extension link AEL2, and a third cathode connection pattern CP3_VSS disposed on the same third metal layer as the first anode extension link AEL1.

As shown in FIG. 19, the anode extension links AEL (i.e., AEL1 and AEL2) are formed using a plurality of metal layers, so that the anode extension links AEL (i.e., AEL1 and AEL2) may be arranged at high density. Accordingly, even if more light emitting devices ED are disposed in the area without the subpixel circuit array SPCA (i.e., first display area DA1), the light emitting devices ED disposed in the area without the subpixel circuit array SPCA may be driven normally.

As shown in FIG. 19, the anode extension links AEL (i.e., AEL1 and AEL2) are formed using a plurality of metal layers, and the anode extension links AEL (i.e., AEL1 and AEL2) may be arranged at high density, so that the first display area DA1 may be enlarged, and the first display area DA1 may be expanded to an area adjacent to the trimming line TRL, as shown in FIG. 6. Therefore, the bezel may be extremely reduced.

Various examples and aspects of the present disclosure are described below. These are provided as examples, and do not limit the scope of the present disclosure.

A display device according to one or more example embodiments of the present disclosure may include a substrate, a display area with a first display area and a second display area, a non-display area outside the display area, a base circuit layer located on the substrate and including a gate-in-panel circuit and a subpixel circuit array disposed in the display area, and a light emitting device layer located on the base circuit layer and including two or more first light emitting devices disposed in the first display area and two or more second light emitting devices disposed in the second display area.

The subpixel circuit array may include one first subpixel circuit configured to simultaneously drive the two or more first light emitting devices, and disposed in the second display area, and two or more second subpixel circuits configured to respectively drive the two or more second light emitting devices, and disposed in the second display area.

The gate-in-panel circuit may be disposed in the first display area, and the subpixel circuit array may be disposed in the second display area.

At least some of the two or more first light emitting devices may overlap with at least a portion of the gate-in-panel circuit. At least some of the two or more second light emitting devices may overlap with at least a portion of the subpixel circuit array.

A display device according to one or more example embodiments of the present disclosure may further include an extension link (if the pixel electrode is an anode, it may also be referred to as an anode extension link) connecting the one first subpixel circuit disposed in the second display area to the two or more first light emitting devices disposed in the first display area.

The extension link may include metal located between the base circuit layer and the light emitting device layer. At least a portion of the extension link may overlap with at least a portion of the gate-in-panel circuit.

The first display area may be located between the non-display area and the second display area.

A display device according to one or more example embodiments of the present disclosure may further include a shielding layer located between the gate-in-panel circuit and the light emitting device layer.

In the case that a display device according to one or more example embodiments of the present disclosure may further include an extension link connecting the one first subpixel circuit to two or more pixel electrodes included in the two or more first light emitting devices, the shielding layer is disposed in the first display area and may be located between the extension link and the gate-in-panel circuit.

At least a portion of the shielding layer may overlap with the extension link and the gate-in-panel circuit. The shielding layer may be disposed in the first display area.

The light emitting device layer may include two or more first anodes disposed in the first display area, two or more first emission layers respectively located on the two or more first anodes, two or more second anodes disposed in the second display area, two or more second emission layers respectively located on the two or more second anodes, and a cathode disposed across the first display area and the second display area, and located on the two or more first emission layers and the two or more second emission layers.

The two or more first light emitting devices may be configured in the first display area by the two or more first anodes, the two or more first emission layers, and the cathode.

The two or more second light emitting devices may be configured in the second display area by the two or more second anodes, the two or more second emission layers, and the cathode.

A base voltage may be applied to the cathode.

A display device according to one or more example embodiments of the present disclosure may further include a base voltage line to which the base voltage is applied, and a cathode connection pattern for electrically connecting the cathode and the base voltage line.

A display device according to one or more example embodiments of the present disclosure may further include an anode extension link connecting the one first subpixel circuit to the two or more first light emitting devices.

The cathode connection pattern may include a first cathode connection pattern disposed on the same metal layer as the anode extension link.

The base voltage line and the cathode connection pattern may be located in the non-display area.

The base voltage line may be disposed outside the gate-in-panel circuit.

A display device according to one or more example embodiments of the present disclosure may further include a shielding layer located between the gate-in-panel circuit and the light emitting device layer, and disposed in the first display area. In this case, the shielding layer may be electrically connected to the cathode connection pattern.

The base voltage line and the cathode connection pattern may be located in the display area.

The cathode may be electrically connected to at least one of the base voltage line and the cathode connection pattern through a hole in the bank located between the two or more second anodes. The base voltage line and cathode connection patterns may be located below the bank.

The light emitting device layer may further include two or more third anodes disposed in the first display area, and two or more third emission layers respectively located on the two or more third anodes.

Two or more third light emitting devices may be configured in the first display area by the two or more third anodes, the two or more third emission layer and the cathode.

The subpixel circuit array may be configured to simultaneously drive the two or more third light emitting devices, and may further include one third subpixel circuit disposed in the first display area.

A display device according to one or more example embodiments of the present disclosure may further include a first anode extension link connecting the one first subpixel circuit disposed in the second display area with the two or more first light emitting devices disposed in the first display area, and a second anode extension link connecting the one third subpixel circuit disposed in the second display area with the two or more third light emitting devices disposed in the first display area.

The first anode extension link and the second anode extension link may be located between the base circuit layer and the light emitting device layer, and may be disposed on different metal layers.

The cathode connection pattern may include a first cathode connection pattern disposed on the same metal layer as the first anode extension link, and a second cathode connection pattern disposed on the same metal layer as the second anode extension link.

A display panel according to one or more example embodiments of the present disclosure may include a substrate, a display area with a first display area and a second display area, a non-display area outside the display area, two or more first light emitting devices disposed in the first display area, a plurality of second light emitting devices disposed in the second display area, one first subpixel circuit commonly connected to the two or more first light emitting devices, and two or more second subpixel circuits. Each of the two or more second subpixel circuits may be connected to one second light emitting device among the plurality of second light emitting devices.

A display panel according to one or more example embodiments of the present disclosure may further include a gate-in-panel circuit disposed in the first display area.

In a display panel according to one or more example embodiments of the present disclosure, the gate-in-panel circuit may be disposed in the first display area, and one first subpixel circuit and two or more second subpixel circuits may be disposed in the second display area.

A display panel according to one or more example embodiments of the present disclosure may further include an extension link commonly connecting a pixel electrode of each of the two or more first light emitting devices to the one first subpixel circuit. That is, the extension link may commonly connect the pixel electrodes (e.g., first anodes) of two or more first light emitting devices to one first subpixel circuit. In one first subpixel circuit, the point where the pixel electrodes (e.g., first anode) of each of the two or more first light emitting devices are connected may be a node electrically connected to the pixel electrode (e.g., the first node N1 in FIG. 2, the fourth node N4 in FIG. 9, or the second node N2 in FIG. 11).

A display panel according to one or more example embodiments of the present disclosure may further include a metal layer disposed between the gate-in-panel circuit and the extension link. A signal with a constant voltage level may be applied to the metal layer.

A display panel according to one or more example embodiments of the present disclosure may further include a shielding layer disposed between the gate-in-panel circuit and the extension link. The shielding layer may be included in the metal layer.

A driving voltage applied to a common electrode for configuring the two or more first light emitting devices and the plurality of second light emitting devices may be applied to the shielding layer. The driving voltage may be the signal with a constant voltage level.

For example, the common electrode may be a cathode, and the driving voltage applied to the common electrode may be the cathode voltage and the base voltage. In this case, the shielding layer may be electrically connected to at least one of the base voltage line, the cathode, and the cathode connection pattern. Here, the cathode connection pattern may be a pattern which connects the cathode and the base voltage line.

A display apparatus according to one or more example embodiments of the present disclosure may include a substrate, a display area for displaying an image, a light emitting device layer disposed over the substrate and including a plurality of light emitting devices disposed in the display area, and a base circuit layer disposed between the light emitting device layer and the substrate and including a gate driving circuit and subpixel circuits.

The gate driving circuit and the subpixel circuits may be disposed in the display area, at least a portion of the gate driving circuit may overlap with one or more first light emitting devices among the plurality of light emitting devices, and at least a portion of the subpixel circuits may overlap with one or more second light emitting devices among the plurality of light emitting devices.

A cathode may be disposed on emission layers of the plurality of light emitting devices. The cathode may overlap with the at least a portion of the gate driving circuit and the at least a portion of the subpixel circuits.

The gate driving circuit (e.g., GIPC of FIGS. 15 and 17-19) may transmit a scan signal or an emission control signal to a scan line or an emission control line of the subpixel circuits (e.g., SPC1, SPC2, and/or SPC1′ of FIGS. 15 and 17-19). The gate driving circuit (e.g., GIPC of FIGS. 15 and 17-19) may control or drive gates of one or more of the subpixel circuits (e.g., SPC1, SPC2, and/or SPC1′ of FIGS. 15 and 17-19).

One or more of the subpixel circuits may drive the one or more second light emitting devices.

In one or more examples, the display apparatus may include, or may be, a display device. In one or more examples, the display apparatus may include, or may be, a display panel. In one or more examples, the display apparatus may include, or may be, a device having electronic and optical components.

In one or more examples, the gate driving circuit may include a gate-in-panel circuit. In one or more examples, the subpixel circuits may include a subpixel circuit array.

According to the one or more example embodiments of the present disclosure, there may provide a display panel and a display device having an extremely narrow bezel structure.

According to the one or more example embodiments of the present disclosure, a gate-in-panel circuit which is a gate driving circuit of the gate-in-panel type may be disposed in the display area, thereby reducing the size of the non-display area.

According to one or more example embodiments of the present disclosure, the gate-in-panel circuit is arranged to overlap the light emitting device layer in the vertical direction, thereby reducing the size of the non-display area.

According to one or more example embodiments of the present disclosure, there may provide a structure capable of shielding the electric field between the gate-in-panel circuit and the light emitting device layer, thereby eliminating unnecessary electrical effect between the gate-in-panel circuit and the light emitting device layer.

According to one or more example embodiments of the present disclosure, a connection structure between the cathode and the base voltage line is disposed in the display area, thereby further reducing the size of the non-display area.

According to one or more example embodiments of the present disclosure, the gate driving circuit and the cathode connection structure are disposed in the display area, so that a length of a path through which a gate signal output from the gate driving circuit is supplied to the subpixel circuits may be shortened, and a length of the cathode connection structure may also be shortened. The hangers on the structure may also be shortened. Accordingly, it is possible to reduce the metal used in the path, thereby enabling the lightening of display panel and a display device.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device, comprising:
a substrate;
a display area with a first display area and a second display area;
a non-display area outside the display area;
a base circuit layer located on the substrate and including a gate-in-panel circuit and a subpixel circuit array disposed in the display area; and
a light emitting device layer located on the base circuit layer, and including two or more first light emitting devices disposed in the first display area and two or more second light emitting devices disposed in the second display area,
wherein the subpixel circuit array comprises:
one first subpixel circuit configured to simultaneously drive the two or more first light emitting devices, and disposed in the second display area; and
two or more second subpixel circuits configured to respectively drive the two or more second light emitting devices, and disposed in the second display area.

2. The display device of claim 1, wherein the gate-in-panel circuit is disposed in the first display area, and the subpixel circuit array is disposed in the second display area.

3. The display device of claim 1, wherein at least some of the two or more first light emitting devices overlap with at least a portion of the gate-in-panel circuit, and
wherein at least some of the two or more second light emitting devices overlap with at least a portion of the subpixel circuit array.

4. The display device of claim 1, further comprising an extension link connecting the one first subpixel circuit disposed in the second display area to the two or more first light emitting devices disposed in the first display area,
wherein at least a portion of the extension link overlaps with at least a portion of the gate-in-panel circuit.

5. The display device of claim 1, wherein the first display area is located between the non-display area and the second display area.

6. The display device of claim 1, further comprising a shielding layer located between the gate-in-panel circuit and the light emitting device layer.

7. The display device of claim 6, further comprising an extension link connecting the one first subpixel circuit to two or more pixel electrodes included in the two or more first light emitting devices,
wherein the shielding layer is disposed in the first display area and is located between the extension link and the gate-in-panel circuit, and
wherein at least a portion of the shielding layer overlaps with the extension link and the gate-in-panel circuit.

8. The display device of claim 1, wherein the light emitting device layer comprises:
two or more first anodes disposed in the first display area;
two or more first emission layers respectively located on the two or more first anodes;
two or more second anodes disposed in the second display area;
two or more second emission layers respectively located on the two or more second anodes; and
a cathode disposed across the first display area and the second display area, and located on the two or more first emission layers and the two or more second emission layers,
wherein a base voltage is to be applied to the cathode,
wherein the two or more first light emitting devices are configured in the first display area by the two or more first anodes, the two or more first emission layers, and the cathode,
wherein the two or more second light emitting devices are configured in the second display area by the two or more second anodes, the two or more second emission layers, and the cathode, and
wherein the display device further comprises a base voltage line to which the base voltage is to be applied, and a cathode connection pattern for electrically connecting the cathode and the base voltage line.

9. The display device of claim 8, further comprising an anode extension link connecting the one first subpixel circuit to the two or more first light emitting devices,
wherein the cathode connection pattern includes a first cathode connection pattern disposed on a same metal layer as the anode extension link.

10. The display device of claim 8, wherein the base voltage line and the cathode connection pattern are located in the non-display area, and
wherein the base voltage line is disposed outside the gate-in-panel circuit.

11. The display device of claim 10, further comprising a shielding layer located between the gate-in-panel circuit and the light emitting device layer, and disposed in the first display area,
wherein the shielding layer is for being electrically connected to at least one of the cathode, the base voltage line and the cathode connection pattern.

12. The display device of claim 8, wherein the base voltage line and the cathode connection pattern are located in the display area, and
wherein the cathode is for being electrically connected to at least one of the base voltage line and the cathode connection pattern located below a bank through a hole in the bank located between the two or more second anodes.

13. The display device of claim 8, wherein the light emitting device layer further comprises two or more third anodes disposed in the first display area, and two or more third emission layers respectively located on the two or more third anodes,
wherein two or more third light emitting devices are configured in the first display area by the two or more third anodes, the two or more third emission layer and the cathode,
wherein the subpixel circuit array further includes one third subpixel circuit disposed in the second display area, and configured to simultaneously drive the two or more third light emitting devices, and
wherein the display device further comprises:
a first anode extension link connecting the one first subpixel circuit disposed in the second display area with the two or more first light emitting devices disposed in the first display area; and
a second anode extension link connecting the one third subpixel circuit disposed in the second display area with the two or more third light emitting devices disposed in the first display area.

14. The display device of claim 13, wherein the first anode extension link and the second anode extension link are located between the base circuit layer and the light emitting device layer, and are disposed on different metal layers.

15. A display panel, comprising:
a substrate;
a display area with a first display area and a second display area;
a non-display area outside the display area;
two or more first light emitting devices disposed in the first display area;
a plurality of second light emitting devices disposed in the second display area;
one first subpixel circuit commonly connected to the two or more first light emitting devices; and
two or more second subpixel circuits,
wherein each of the two or more second subpixel circuits is connected to one second light emitting device among the plurality of second light emitting devices.

16. The display panel of claim 15, further comprising a gate-in-panel circuit disposed in the first display area,
wherein the one first subpixel circuit and the two or more second subpixel circuits are disposed in the second display area.

17. The display panel of claim 16, further comprising an extension link commonly connecting a pixel electrode of each of the two or more first light emitting devices to the one first subpixel circuit.

18. The display panel of claim 17, further comprising a metal layer disposed between the gate-in-panel circuit and the extension link,
wherein a signal with a constant voltage level is for being applied to the metal layer.

19. A display apparatus, comprising:
a substrate;
a display area;
a light emitting device layer disposed over the substrate and including a plurality of light emitting devices disposed in the display area; and
a base circuit layer disposed between the light emitting device layer and the substrate, and including a gate driving circuit and subpixel circuits,
wherein:
the gate driving circuit and the subpixel circuits are disposed in the display area;
at least a portion of the gate driving circuit overlaps with one or more first light emitting devices among the plurality of light emitting devices; and
at least a portion of the subpixel circuits overlaps with one or more second light emitting devices among the plurality of light emitting devices.

20. The display apparatus of claim 19, wherein:
a cathode is disposed on emission layers of the plurality of light emitting devices;
the cathode overlaps with the at least a portion of the gate driving circuit and the at least a portion of the subpixel circuits;
the gate driving circuit is configured to transmit a scan signal or an emission control signal to a scan line or an emission control line of the subpixel circuits; and
one or more of the subpixel circuits are configured to drive the one or more second light emitting devices.
